(19) United States
(12) Patent Application Publication
(10) Pub. No.: US 2024/0278991 A1
(43) Pub. Date: Aug. 22, 2024

(54) IN-LINE MACHINE VISION SYSTEM FOR PART TRACKING OF SUBSTRATE PROCESSING SYSTEM

(71) Applicant: Lam Research Corporation, Fremont, CA (US)

(72) Inventors: Hossein Sadeghi, San Jose, CA (US); Damon Tyrone Genetti, Livermore, CA (US); Deqi Wang, San Jose, CA (US); Scott Baldwin, Reston, VA (US)

(21) Appl. No.: 18/570,061

(22) PCT Filed: Jun. 15, 2022
(86) PCT No.: PCT/US22/33694

§ 371 Date: Dec. 13, 2023

Related U.S. Application Data
(60) Provisional application No. 63/214,681, filed on Jun. 24, 2021.

(51) Int. Cl. B65G 1/137; B25J 11/00; G06K 7/14; H01L 21/67

(52) U.S. Cl. CPC B65G 1/1371; G06K 7/1417; H01L 21/67294; B25J 11/0095; B65G 2203/0216; B65G 2203/041

(57) ABSTRACT

Systems for tracking consumable parts in a substrate processing system includes a mounting enclosure with a consumable parts station used for storing consumable parts within. The mounting enclosure has an opening toward an EFEM to enable a robot of the EFEM to retrieve a consumable part from the consumable parts station. An image capture system is configured to capture an image of a code on the consumable part. The image capture system includes a camera and a light source. The image capture system is positioned near the opening of the mounting enclosure, such that the camera and the light source are pointed toward the opening. A processor is communicatively connected to the image capture system and to a controller. The controller causes the robot to move the consumable part from the consumable parts station via the opening and to position the code on the consumable part within a field of view of the image capture system. The controller issues a command to the processor to activate the light source and the camera to capture an image of the code, process the image, generate an identifier of the consumable part and forward the identifier to the controller. The controller is configured to use the identifier to verify that the consumable part is suitable for a subsequent operation.

### 1. FIELD OF THE DISCLOSURE

The present embodiments relate to semiconductor wafer processing, and more particularly, to tracking of consumable parts provided to a process module within a substrate processing system.

### 2. DESCRIPTION OF THE RELATED ART

A typical fabrication system includes a plurality of cluster tool assemblies or processing stations. Each processing station used in the manufacturing process of a semiconductor wafer includes one or more process modules with each process module used to perform a specific manufacturing operation. Some of the manufacturing operations performed within the different process modules include, a cleaning operation, an etching operation, a deposition operation, a rinsing operation, a drying operation, etc. The process chemistries, process conditions and processes used in the process modules to perform these operations cause damage to some of the hardware components that are constantly exposed to the harsh conditions within the process modules. These damaged or worn out hardware components need to be replaced periodically and promptly to ensure that the damaged hardware components do not expose other hardware components in the process modules to the harsh conditions, and to ensure quality of the semiconductor wafer. Some of the hardware components that may get damaged due to its location and continuous exposure to harsh chemistries and processes performed within the process module include edge rings, cover rings, etc., that surround the wafer. An edge ring may get eroded after certain number of process cycles and needs to be replaced promptly to ensure that the eroded edge ring does not expose the underlying hardware components, such as a chuck, a ground ring, etc., to the harsh process conditions. The hardware components that can be replaced are referred to herein as consumable parts.

Consumable parts, such as edge rings, are highly critical to process performance. These consumable parts are typically replaced manually and require venting of the process module for exchanging the edge ring. Alternately, the consumable parts are replaced using an automated approach involving loading new edge rings into a buffer station (e.g., a FORP (front opening ring pod-edge ring exchange station) that is similar to a Front Opening Unified Pod (FOUP) used for buffering wafers (wafer exchange station), transporting the edge ring from the FORP to a load port of a processing station, and using the system robotics to remove an old edge ring from a process module and install a new edge ring. The replacement of the consumable parts is performed under vacuum in a manner similar to the transport of a wafer to and from a process module. The edge ring can be transported from the buffer station through a fab automated material handling system (AMHS) that is used for transporting wafer from the wafer exchange station. A single buffer station may be used to store both new edge rings and worn out edge rings that are removed from the process module or different buffer stations may be used for separately storing new edge rings and used edge rings. Worn out edge rings need to be promptly disposed of and when entirely used up, new edge rings need to be loaded.

The exact shape and height of an edge ring is optimized based on the process application. As a result, there is a multitude of different edge rings that are in use and need to be efficiently managed. The differences in the different types of edge rings are often very slight and imperceptible to the eye. Furthermore, once in the buffer station, it becomes nearly impossible to distinguish among different edge rings. In a production environment, the edge ring buffer stations could contain a single type of edge rings, more than one type of edge rings, or edge rings of a single type or multiple types mixed with other consumable parts. The edge rings are typically loaded manually into different slots of the buffer stations and the loaded edge rings are registered on the system computer. There is room for error during the manual loading/registering process. For instance, a user may load the edge ring into a wrong slot (e.g., load the edge ring into slot 2 instead of slot 1). Alternately, the user may enter incorrect information (such as serial number, part number, slot number, dimensions, etc.,) for the edge ring loaded into a particular slot of the buffer station. Such errors may lead to a wrong edge ring being delivered to a process module within the cluster tool. For example, an incorrect edge ring accidentally loaded to a process module would lead to wafer scrap events that are unacceptable. Such issues may go undetected for a considerable length of time and may significantly affect the quality of the wafers that are being processed, thereby severely impacting the profit margin for a semiconductor manufacturer. Currently, there is no efficient way to automatically verify that the correct edge rings are being loaded into the FORP or to determine their location (i.e., slot number) in the tool.

It is in this context that embodiments of the invention arise.

### SUMMARY

Embodiments of the disclosure include systems and methods for tracking an edge ring and verifying identity of the edge ring so that a correct edge ring may be delivered to a correct process module within a substrate processing system. The tracking is done using a machine vision system and an aligner disposed on an arm of a robot used within the substrate processing system (i.e., such as a cluster tool). The substrate processing system or the cluster tool includes an atmospheric transfer module (ATM) coupled to a vacuum transfer module (VTM) through one or more loadlocks, and the VTM is coupled to one or more process modules. A robot of the ATM and a robot of the VTM are used to move wafers between a wafer buffer station and one or more process modules. The robot of the ATM is equipped with an aligner that is used to align the wafer prior to delivering the wafer to the process module. The aligned wafer is then received over a substrate surface for processing. The robots of the ATM and the VTM are also used to move the consumable parts between a process module and a consumable parts station that is used for storing consumable parts. An identifier is disposed on each of the consumable parts. In some implementations, the identifier may be a code (e.g., machine readable code) disposed on a top surface, on a bottom surface, both on the top and bottom surfaces, or somewhere between the top and the bottom surfaces of the consumable part. In some implementations, the machine vision system is used to capture image of the code disposed on the consumable part and process the image to identify the consumable part and the aligner of the robot is used to align the code on the consumable part above the machine vision system so that the image of the code can be captured by a camera or a image capturing device of the machine vision system. In some implementations, the image of the code is verified against a consumable parts database to determine if the consumable part that is scheduled for delivery to a process module is appropriate for the process module. Once the identity of the consumable is successfully verified, the consumable part is delivered to the process module for installation.

The machine vision system provides additional verification of the consumable part to avoid providing incorrect consumable parts to a process module within the substrate processing system due to human introduced errors. Due to huge variance in the types of consumable parts that are available and used in the different process modules, it is important to keep track of the different types of consumable parts (e.g., edge rings) used in the different process modules, and to deliver a correct type of consumable part(s) to each process module within different processing stations in order to optimize the processes performed therein. The machine vision system performs automated verification thereby saving considerable time and cost.

To assist in tracking the consumable parts, such as edge rings, in some implementations, a code is defined on the consumable part and the consumable parts are tracked by verifying the code against a consumable parts database. When a consumable part is being retrieved for delivery to a process module, the consumable part is first identified and then verified prior to delivery to the process module. As part of verification, in some implementations, an image of the code is captured using the machine vision system, and the captured image is processed to identify the code and generate an identifier for the consumable part. The consumable part identifier is verified against the consumable parts database that includes information related to the different types of consumable parts and the different process modules within a fabrication facility that uses each type of consumable part. Upon successful verification, the consumable part is then transported by the robots of the ATM and the VTM to the process module. Keeping track of each consumable part ensures that the correct consumable part is delivered to each process module, thereby eliminating any loading errors (e.g., incorrect information recorded for a consumable part during loading or incorrect loading of the consumable part into a slot in the consumable parts station). The tracking and verification ensures that an incorrect consumable part is not erroneously loaded into a process module, thus avoiding unnecessary wafer scraps from such errors.

In one implementation, a machine vision system for tracking and verifying a consumable part in a substrate processing system, is disclosed. In some implementations, the machine vision system includes a mounting, enclosure, an image capture system, a processor (e.g., an edge processor) and a controller. The mounting enclosure has a consumable parts station for storing consumable parts within. The mounting enclosure has an opening towards an equipment front end module (EFEM) of the substrate processing system to enable a robot in the EFEM to retrieve a consumable part from the consumable parts station. The image capture system is configured to capture an image of a code on the consumable part. The image capture system includes a camera, and light source. The image capture system is positioned near the opening of the mounting enclosure and is oriented to point toward the opening. The processor is communicatively connected to the image capture system and to a controller of the substrate processing system. The processor is configured to process and analyze the image of the code captured by the image capture system and generate an identifier for the consumable part that is returned to the controller. The controller is configured to issue a command to cause the robot to move the consumable part from the consumable parts station via the opening of the mounting enclosure so as to position the code of the consumable part within a field of view of the image capture system. The controller is further configured to, in response to the identifier provided by the processor, verify that the consumable part is suitable for a subsequent operation.

In one implementation, the processor is configured to interact with, (a) an image enhancement module to enhance the image of the code captured by the image capture system, (b) a decoder to decode an enhanced image and generate a string identifying the consumable part, and (c) a communications module to communicate the string identifying the consumable part to the controller for verification.

In one implementation, the controller is configured to provide signals to the processor to activate the light source and to initiate the camera to capture of the image of the code, and verify the consumable part using the string forwarded by the processor.

In one implementation, the light source includes a plurality of light elements, location of the plurality of light elements is defined to illuminate the code and to provide an overlapping region, that at least covers an area on the surface of the consumable part where the code is present, when the consumable part is positioned in a read orientation.

In one implementation, the robot includes an aligner that is used to align the consumable part to the read orientation.

In one implementation, the aligner is configured to detect a fiducial marker disposed on the consumable part, wherein the fiducial marker is disposed at a pre-defined angle from the code of the consumable part. The robot is caused to move the consumable part based on instructions from the controller. The instructions from the controller specifies the pre-defined angle to move the consumable part in relation to the fiducial marker so as to align the code within the field of view of the camera of the image capture system for capturing the image of the code illuminated by the light source.

In one implementation, the read orientation is defined to correspond with an open region of the consumable part that is not covered by an end-effector of the robot so as to provide an unhindered view of the code for the camera for capturing the image.

In one implementation, the image capture system includes a transparent cover defined in a top portion facing the opening of the mounting enclosure. The transparent cover configured to shield the camera and the light source of the image capture system.

In one implementation, the camera of the image capture system is disposed at a first distance from the surface of the consumable part on which the code is disposed, and the light source includes a plurality of light elements, wherein each light element of the plurality of light elements is separated from one another light element by a second distance.

In one implementation, the first distance is proportional to the second distance and is defined to be between about 1:1.3 and about 1:1.7.

In one implementation, the image capture system includes diffusers, or polarizers or both diffusers and polarizers. The light source is a pair of light emitting diodes. Each diffuser, when present, is disposed in front of each one or both of the pair of light emitting diodes at a predefined first distance. Similarly, each polarizer, when present, is disposed in front of one or both of the pair of light emitting diodes at a predefined second distance, or in front of lens of the camera at a predefined third distance, or in front of both the lens of the camera at the predefined second distance and one or both of the pair of light emitting diodes at the predefined third distance.

In one implementation, the consumable parts station has an outside wall that is oriented opposite to the opening of the mounting enclosure. The outside wall has a second opening for accessing the consumable parts station for loading and unloading of the consumable parts.

In one implementation, a consumable part in the consumable parts station is made of two parts and the code is disposed on a surface of each part of the two parts. A first code in a first part of the two parts is separated by a predefined distance from a second code in a second part. The robot moves the consumable part based on instructions from the controller. The instructions provided to the robot include a first set of instructions to move the consumable part so as to cause the first code disposed on the first part to be brought within a field of view of the image capture system and to simultaneously activate the light source to illuminate the first code and the camera to capture image of the first code, and a second set of instructions to move the consumable part so as to cause the second code disposed on the second part to be brought within the field of view of the image capture system and to simultaneously activate the light source to illuminate the second code and the camera to capture image of the second code.

In one implementation, the light source is a pair of light emitting diodes that are arranged to illuminate the code tangentially.

In one implementation, the first part and the second part of the two part consumable part is made of same material, wherein the material is one of Quartz or Silicon Carbide.

In one implementation, first part of the two part consumable part is made of different material than the second part, wherein the first part of the two part consumable part is made of Quartz material and the second part is made of Silicon Carbide material.

In one implementation, the processor is an edge processor. The edge processor is configured to store the image of the code, process the image, analyze the image and generate the string identifying the consumable part, and transmit the string to the controller for verification. The edge processor is connected to the controller via an Ethernet switch.

In one implementation, the consumable part is an edge ring that is disposed to be adjacent to a wafer received on wafer support surface within a process module of the substrate processing system.

In one implementation, a robot for tracking consumable parts in a substrate processing system is disclosed. The robot includes an end-effector and an aligner. The end-effector is defined on an arm of the robot and is designed to support a carrier plate used for supporting a consumable part. The aligner is disposed on the arm. The aligner is configured to rotate the carrier plate with the consumable part along an axis. The aligner has a sensor to track a fiducial marker defined on a surface of the consumable part and provide offset coordinates of the fiducial marker to a controller of the substrate processing system. The robot is configured to receive a set of instructions from the controller to cause the robot to d move the consumable part supported on the carrier plate from the consumable parts station and to a read orientation in relation to the fiducial marker, wherein the read orientation is defined to place a code disposed on the surface of the consumable part within a field of view of an image capture system of the substrate processing system to allow the image capture system to capture an image of the code. The image of the code captured by the image capture system is processed to generate an identifier for the consumable part. The identifier is used by the controller for verification of the consumable part.

In one implementation, the image capture system is communicatively connected to the controller. The image capture system receives a second set of instructions from the controller. The second set of instructions includes a first instruction to activate a light source disposed within the image capture system to illuminate the code and a second instruction to activate a camera of the image capture system to initiate capturing of the image of the code.

In one implementation, the fiducial marker is an optical marker defined on the surface of the consumable part at a predefined angle from the code. The read orientation is defined to correspond with an open region of the consumable part that is outside of an area covered by arm extensions of the carrier plate.

In one implementation, the sensor of the aligner is one of a laser sensor or a through beam LED fiber sensor with a liner curtain head on the fibers.

In one implementation, the robot is disposed within an equipment front end module (EFEM) of the substrate processing system. The EFEM provides access to the consumable part stored in a consumable parts station of a mounting enclosure of the substrate processing system. The access to the consumable part is provided to the robot via an opening defined toward the EFEM.

In one implementation, the offset coordinates of the fiducial marker and the image of the code are forwarded by the controller to the image capture system via a processor. The processor interacts with an image enhancing processor to enhance the image of the code captured by the image capture system, interacts with a decoder to decode the image of the code and generate a string identifying the consumable part, interacts with a communication module to communicate the string to the controller for verification of the consumable part.

In one implementation, the end-effector of the robot configured to move the consumable part from the consumable parts station is also configured to move a wafer from a wafer station for delivery to a process module within the substrate processing system. The aligner of the robot is configured to detect a notch within the wafer and control orientation of the wafer in relation to the notch prior to delivery to the process module.

In one implementation, the consumable part is made of a first part and a second part. A first code is disposed on a surface of the first part and a second code is disposed on a surface of a second part. The first code of the first part is separated by a predefined distance from the second code of the second part. The set of instructions provided to the robot include a third instruction to move the consumable part to allow the first code disposed on the first part to be brought to the read orientation in relation to the fiducial marker to allow capture of an image of the first code, and a fourth instruction to move the consumable part to allow the second code disposed on the second part to be brought to the read orientation in relation to the fiducial marker to allow capture of an image of the second code disposed on the second part.

In yet another implementation, a machine vision system for tracking and verifying a consumable part in a substrate processing system is disclosed. The machine vision system includes a mounting enclosure, a controller, an image capture system and a processor. The mounting enclosure has a consumable parts station for storing consumable parts within. The mounting enclosure has an opening towards an equipment front end module (EFEM) of the substrate processing system to enable a robot in the EFEM to retrieve a consumable part from the consumable parts station. The controller is configured to cause the robot in the EFEM to move the consumable part from the consumable parts station via the opening of the mounting enclosure and to position the code of the consumable part within a field of view of the image capture system. The image capture system is configured to capture an image of a code on the consumable part. The image capture system includes at least a camera and a light source. The image capture system is positioned near the opening of the mounting enclosure. The camera and the light source are oriented to point toward the opening of the mounting enclosure. The processor is communicatively connected to the image capture system and the controller. The processor is configured to process and analyze the image of the code captured by the image capture system and verify that the consumable part is suitable for a subsequent operation.

The advantage of tracking the consumable part is to ensure that the consumable part retrieved from the consumable parts station is the correct consumable part that is targeted for a process module within a substrate processing system. The information obtained from tracking can be used to keep track of when the consumable part was provided to a process module and usage history of the consumable part so as to determine when the consumable part in a process module reaches an end of usage life and has to be replaced. These and other advantages will be discussed below and will be appreciated by those skilled in the art upon reading the specification, drawings and the claims.

### BRIEF DESCRIPTION OF THE DRAWINGS

FIG. 1 illustrates a simplified block diagram of a substrate processing system that employs a machine vision system for tracking a consumable part used in the substrate processing system, in one implementation. FIG. 1A illustrates an expanded view of a consumable part used in the substrate processing system, in one implementation.

FIG. 2 illustrates a simplified representation of a machine vision system that includes an image capture system for capturing an image of a code disposed on a consumable part, in one implementation.

FIG. 3 illustrates a simplified representation of various components of a processor of the machine vision system used to identify the consumable part, in one implementation.

FIG. 4 illustrates an overview of the machine vision system used in tracking the consumable part, in one implementation.

FIGS. 5A-5D illustrate different views of an image capture system used to capture image of a code disposed on the consumable part, in one implementation.

FIG. 6 illustrates a portion of an arm of a robot used in an atmospheric transfer module with an aligner sensor used for detecting a fiducial marker disposed on a surface of the consumable part, in one implementation.

FIG. 7A illustrates a top view of a consumable part showing a relative position of a fiducial marker with respect to a code used for tracking the consumable part, in one implementation.

FIG. 7B illustrates a bottom view of the consumable part showing a relative position of the fiducial marker with respect to the code, in one implementation.

FIG. 8A illustrates a consumable part being balanced on a carrier plate supported on a robot arm within a consumable parts station prior to aligning over a image capture system, in one implementation.

FIG. 8B illustrates the consumable part with a code that is in the process of being aligned over the image capture system to enable capture of the code, in one implementation.

FIG. 9A illustrates a simplified rendition of image capture system capturing an image of the code illuminated by a pair of light emitting diodes and aligned over a camera, in one implementation.

FIG. 9B illustrates a two-dimensional rendition of areas of illumination of a pair of light emitting diodes of the image capture system illuminating the code on the consumable part, in one implementation.

FIG. 9C illustrates a sample portion of a code on the consumable part detected from the image of the code captured by the image capture system, in one implementation.

FIG. 9D-1 illustrates variation in surface characteristics where a code is disposed on a consumable part made of a first material and FIG. 9D-2 illustrates a sample code disposed on the surface of the consumable part, in one implementation.

FIG. 9E-1 illustrates variation in surface characteristics where a code is disposed on a consumable part made of a second material and FIG. 9E-2 illustrates a sample code disposed on the surface of the consumable part, in an alternate implementation.

FIG. 10A illustrates an example of a consumable part made of a specific material and location of a code on a surface of the consumable part captured by an image capture system, in one implementation.

FIGS. 10B-1 and 10B-2 illustrate an example of a consumable part made of a first part and a second part, with a first code on the surface of the first part and a second code on the second part, wherein the first part and second part are made of same specific material, in one implementation.

FIGS. 10C-1 and 10C-2 illustrate an example of a consumable part made of a first part and a second part, with a first code on the surface of the first part and a second code on the surface of the second part, wherein the first part and the second part are made of different materials and the first code is disposed at a different depth than the second code, in one implementation.

FIG. 10D illustrates a cross-sectional view of a consumable part (e.g., edge ring) showing different surfaces on which the code can be disposed, in one implementation.

FIG. 10E illustrates a top view of an image of a fiducial marker detected on a surface of the consumable part and FIG. 10F illustrates a bottom view of an image of the fiducial marker defined on the consumable part, in one implementation.

FIG. 11A illustrates a rear view (i.e., backside view) of a consumable parts station that is used to buffer the consumable parts used in substrate processing system, in one implementation.

FIG. 11B illustrates a top view of the consumable parts station illustrated in FIG. 11A, and FIG. 11C shows an expanded view of a top window defined on a top surface of the consumable parts station providing a view of an inside of the consumable parts station, in one implementation.

FIGS. 12A-12D illustrates an alignment of a code disposed on a surface of the consumable part supported on a carrier plate in relation to a fiducial marker to enable capture of an image of the code, in one implementation.

### DETAILED DESCRIPTION

In the following description, numerous specific details are set forth in order to provide a thorough understanding of the present inventive features. It will be apparent, however, to one skilled in the art that the present invention may be practiced without some or all of these specific details. In other instances, well known process operations have not been described in detail in order not to unnecessarily obscure the present invention.

Embodiments of the disclosure provide details of tracking a consumable part, such as an edge ring, using an identifier, such as a code disposed on a surface of the consumable part. The code may be disposed on a bottom surface or a top surface of the consumable part or may be disposed on both the top and the bottom surfaces of the consumable part with the code on the top surface overlapping the code on the bottom surface, or embedded inside the consumable part. The code may be data matrix type code, such as quick response (QR) code, or may be a bar code or a printed character code or any other type of data matrix or identification marker that can be used to identify the consumable part (e.g., edge ring). The tracking is done using a machine vision system which includes an image capture system to illuminate the code and capture an image of the code and a processor to enhance the image, decode the code and generate a string identifying the consumable part. The string identifier is then forwarded to a controller for verification. The controller is used to control various parameters for successful functioning of a substrate processing system. The controller verifies the information against a consumable parts database to determine the identity of the consumable part and the type of process modules in which the consumable part is used.

When a process module requires an edge ring replacement, for example, a robot of the substrate processing system is used to retrieve an edge ring from a consumable parts station that stores the consumable parts used in the different process modules of the substrate processing system. The consumable parts station provides a temporary storage for the consumable parts (i.e., storage prior to delivery to process module and storage after retrieval from process module) and hence such storing may alternatively be referred to herein as “buffering”. The process modules within the substrate processing system and the process modules within the different substrate processing systems within a fabrication facility may use different types of consumable parts, wherein each type of consumable part may vary from other types in a small way or in a substantial way. In some cases, the consumable part may be a multi-part consumable part (e.g., a stacked consumable part), wherein the parts interlock with one another or may rest one on top of another. In such cases, each part of the multi-part consumable part may have a code disposed on the surface of the respective part and the machine vision system is configured to detect the number of parts in the consumable part and capture the image of the code of each part to identify the consumable part as a whole.

In some implementations, a robot in the substrate processing system moves the consumable part so that the code is positioned to align within field of view and in depth of field of the image capture system to allow the image capture system to capture an image of the code. The image capture system of the machine vision system includes an image capturing device, such as a camera (with lens), to capture the image of the code on the consumable part, and at least lighting sources, such as light emitting diodes, to illuminate the area of the consumable part where the code is disposed, so that the image captured by the camera is sharp and can be easily deciphered. In response to detecting the consumable part aligned with the image capture system, the controller generates a signal to the processor capture the image of the code disposed on the consumable part. The processor, in response, sends signals to, (a) activate the lighting source (e.g., light emitting diodes) to illuminate the area with the code on the consumable part that is aligned with the image capture system and (b) activate the camera so that the camera can capture the image of the code disposed on the consumable part.

The captured image is then analyzed and decoded to determine the identification information contained therein. The decoded information is used to generate a string (also referred to as a “string identifier”) identifying the consumable part. The string identifier is forwarded to the controller for verification. The controller includes software that is configured to perform the verification of the consumable part by querying a consumable parts database to determine the identity of the consumable part and the types of process modules that use the consumable part. Upon successful verification of the consumable part by the software, the software then directs the robot to move the consumable part for delivery to the process module. The tracking and verification of the consumable part ensures that the correct consumable part is being delivered to the appropriate process module, thereby eliminating incorrect consumable part from being delivered to the process module. With the above general understanding of the implementation, various specific details will now be described with reference to the various drawings.

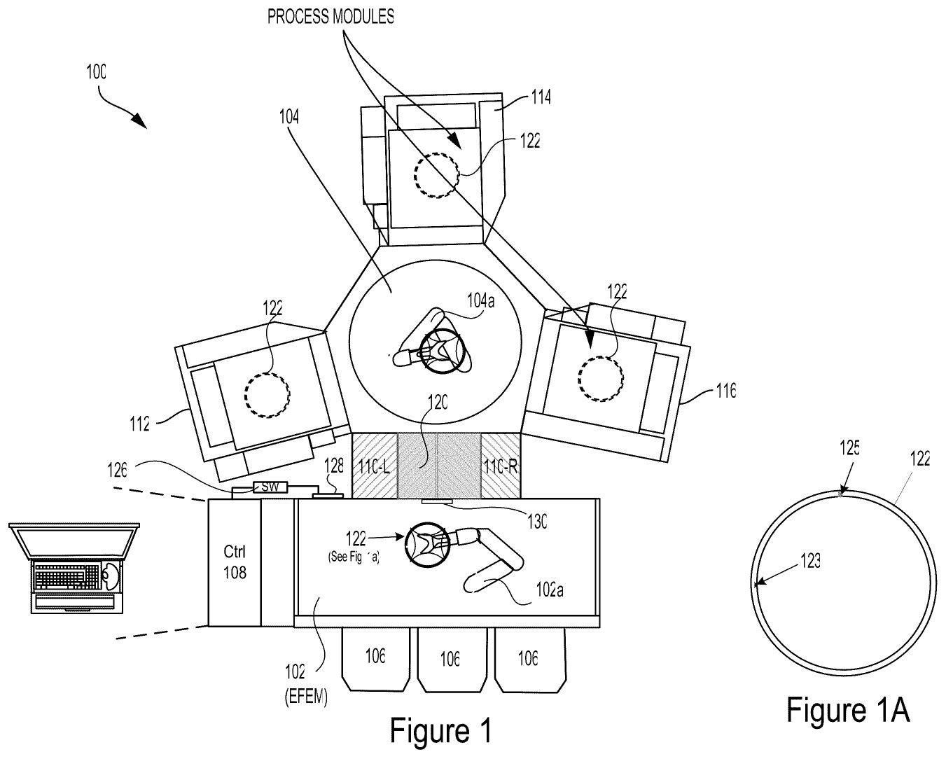

FIG. 1 illustrates a simplified block diagram of an example substrate processing system 100 in which consumable parts, such as edge rings, used within various process modules are tracked, in one implementation. The illustrated substrate processing system may be part of a fabrication facility wherein a plurality of such substrate processing systems may be employed. The substrate processing system 100 includes a plurality of modules, such as equipment front end module (EFEM—also referred to herein as atmospheric transfer module or ATM) 102, one or more loadlocks 110, a vacuum transfer module (VTM) 104, and one or more process modules 112-116, that are controlled by signals from a controller 108. The EFEM 102 is maintained in atmospheric condition and includes one or more load ports 106 defined on a first side and configured to receive one or more wafer stations. The wafer stations on the load ports 106 are accessed via an opening controlled by one or more isolation valves. The wafer stations buffer a plurality of wafers (i.e., semiconductor substrates) that are provided to the process modules 112-116 for processing to define semiconductor devices. The wafers are retrieved from the wafer stations by a robot (also referred to as ATM robot 102a) within the EFEM 102. The ATM robot 102a includes an arm on which an end-effector is disposed. The end-effector is configured to support the wafers retrieved from the wafer stations and deliver the wafers to the loadlock 110 for onward delivery to a process module (112-116). The ATM robot 102a is also configured to support a carrier plate on which a consumable part can be supported. Use of the carrier plate allows the same end-effector of the ATM robot 102a that is used to transfer the wafers to also transfer the consumable parts to the loadlock 110 for onward transmission to process modules 112-116 without requiring re-designing of the end-effector.

In the implementation illustrated in FIG. 1, the substrate processing system 100 includes a pair of loadlocks, 110-L, 110-R that is coupled to the EFEM 102 on one side and the VTM 104 on the other side. The loadlocks 110-L, 110-R, act as intermediary modules between the EFEM 102 that is maintained in atmospheric condition and the vacuum transfer module (VTM) 104 that is maintained in vacuum (i.e., in controlled environment). The loadlocks 110-L, 110-R, are disposed on a second side of the EFEM 102. In one implementation, the second side is defined to be opposite to the first side. In alternate implementation, the second side may be defined to be adjacent to the first side. Each of the loadlocks 110-L, 110-R, includes a first isolation valve (not shown) on the side that is coupled to the EFEM 102 and a second isolation valve (not shown) on the side that is coupled to the VTM 104. When a wafer from the wafer station is to be delivered to the loadlock (e.g., 110-L), the first isolation valve of the loadlock 110-L is opened and the second isolation valve is kept closed. Once the wafer is delivered to the loadlock 110-L, the first isolation valve is closed. The loadlock is then pumped to vacuum while both the first and the second isolation valves are kept closed. Once the loadlock 110-L has reached vacuum, the second isolation valve is opened and a VTM robot 104a of the VTM 104 is then used to move the wafer from the loadlock to the appropriate process module 112-116 for processing.

When a consumable part 122, such as an edge ring is to be replaced in a process module 112-116, similar process as the one used for wafer delivery is followed. In the case of the consumable part 122, the consumable part is retrieved from the consumable parts station 120 by the ATM robot 102a of the EFEM 102 and delivered to one of the loadlocks 110-L or 110-R for onward delivery to a process module 112-116. In one implementation, the consumable parts station 120 is disposed on the same side as the loadlocks 110-L, 110-R and is defined above the loadlocks 110-L, 110-R. The consumable parts station 120 may include a plurality of slots into which the consumable parts 122 are buffered or stored. An end-effector disposed on an arm of the ATM robot 102a reaches into the consumable parts station 120 to first retrieve a carrier plate (not shown). After retrieving the carrier plate, the ATM robot 102a then retrieves a consumable part 122 from one of the slots in the consumable parts station 120 and balances the consumable part 122 on the carrier plate. The consumable part 122 is then moved out of the consumable parts station 120 into the EFEM 102.

The process of replacing the consumable part 122 in a process module may be done based on a signal from an operator, or a signal from a controller that keeps track of the various parameters of the substrate processing system, or from a signal from a process module. The signal may be generated based on the usage life left on the consumable part. For instance, if the consumable part has reached the end of its usage life or has usage life that is less than the time needed for a process cycle of a process performed within a process module, the signal may be generated automatically by the process module. Alternately, the signal may be generated by the controller or may be manually initiated by an operator to replace the consumable part in the process module. In response to the signal, the controller may send a set of instructions to the ATM robot 102a to retrieve a consumable part stored in the consumable parts station 120 and move the consumable part out of the consumable parts station 120 and into the EFEM 102. In one implementation, the controller may query a consumable parts database to identify the type of consumable part that is used in the process module. The consumable parts database is a repository of all the consumable parts used in the various tools within a fabrication facility in which the substrate processing system is located. In addition to the type of consumable parts used, the consumable parts database may maintain the history of use of the different types of consumable parts used in the different process modules. For instance, the consumable parts database may maintain a list and status (new, used, usage life left, type, process modules that use each type of consumable part, etc.,) of the consumable parts that are loaded into the different slots of consumable parts station. The list of consumable parts may be provided by an operator during manual loading or by an automated system (e.g., by a robot or an automated consumable parts handling system) during loading of the consumable parts into the consumable parts station. For instance, new consumable parts may be loaded into one of slots 1-5 (e.g., slots within new parts section) in the consumable parts station by an operator or by a robot and a used consumable part that was removed from a process module may be loaded into slots 6-10 (e.g., slots within used parts section). In response to a signal for replacing the consumable part in a process module, the controller may query the consumable parts database to identify a slot number from where the consumable part has to be retrieved for delivery to the process station. The slot number may be provided in the set of instructions provided by the controller to the ATM robot 102a. Responsive to the instructions, the end-effector of the ATM robot 102a reaches into the consumable parts station and retrieves the consumable part from the identified slot. The retrieved consumable part 122 is verified to ensure that the consumable part details registered in the consumable parts database actually corresponds to the consumable part retrieved from the identified slot, prior to delivering the consumable part to the process module. It is to be noted herein that the consumable part, as used in this application, can include any replaceable parts used in the process module.

Each of the consumable parts 122 in the consumable parts station 120 is equipped with an identifier, such as a quick response (QR) code 125 (FIG. 1A). In some implementations, in addition to the QR code 125, a fiducial marker 123 is also disposed on the consumable part 122. FIG. 1A illustrates one such implementation wherein an edge ring (i.e., a consumable part) 122 includes a fiducial marker 123 and a QR code 125. The fiducial marker 123 may be an optical marker that is disposed at a predefined angle from the QR code 125 and is used for aligning the consumable part 122. When the end-effector of the ATM robot 102a retrieves the consumable part 122 from the consumable parts station 120, an aligner (not shown) disposed on the arm of the ATM robot 102a is used to align the consumable part 122 by tracking the fiducial marker 123 and aligning the consumable part 122 in relation to the fiducial marker 123 so that the QR code 125 is aligned over a field of view and a depth of field of an image capture system 130 disposed in the EFEM 102. In one implementation, the image capture system 130 is disposed below an opening of the EFEM 102 into the consumable parts station 120. The image capture system 130 is not limited to being disposed below the opening but can also be disposed above the opening or in any other location in the EFEM 102 that enables capturing a clear image of the QR code 125 on the consumable part 122. As the consumable part is aligned over the image capture system 130, a light source, such as a pair of light emitting diodes, is activated to illuminate the region of the consumable part 122 with the QR code, and an image capturing device (e.g., camera) is activated to capture the image of the QR code 125.

The captured image is processed by a processor 128 to which the image capture system 130 is coupled to, in order to obtain information related to the QR code 125 that includes identification information of the consumable part 122. In one implementation, the processor that processes the captured image is an edge processor. An edge processor is defined as a computing device that is at the edge of a process network and is used to perform the operations of capturing, storing, processing and analyzing data near where the data is generated/captured (i.e., at the edge of the process network). In the current implementation, the image data captured by the image capture system is processed, stored and analyzed locally at the edge processor where the image data is captured (i.e., collected), and a string representing an identifier of the consumable part is generated. The edge processor is configured to perform the basic computation of the data collected by the image capture system and transmit minimal data (i.e., result of the computation—string identifier of the consumable part) to the controller, thereby reducing the amount of bandwidth consumed during data transmission to the controller (i.e., centralized computing device). This results in optimal bandwidth consumption as most of the data is filtered and processed locally at the edge processor instead of being transmitted to the controller and/or centralized computing device for processing and storing. The advantages of using the edge processor (i.e., edge computing) includes speed of processing data (i.e., more data processed locally and less data transmitted to other computing devices), optimal bandwidth usage, security, scalability, versatility, and reliability. It is noted that although throughout the application, the capturing, storing, and analyzing of image data is defined to be done using an “edge processor,” the various implementations are not restricted to the use of edge processor. Instead, other types of processors can also be envisioned, wherein some portion of the processing is performed locally and the remaining portion is done at a controller or other computing device (including a cloud computing device).

The identification information of the consumable part 122 embedded in a string is then forwarded to a software 126 for further processing. The software 126 may be a separate processor coupled to a controller 108 or may be deployed on the controller 108. The controller 108 may be part of a computing device that is local to the substrate processing system 100, or may be a computing device coupled to a remote computing device, such as a cloud computing device, via a network, such as Internet or Wifi. The software 126 uses the identification information of the consumable part 122 included in the string to query a consumable parts database that is available to the controller 108 to verify that the consumable part 122 retrieved from the consumable parts station 120 is a valid consumable part used in the substrate processing system 100, and specification of the process module(s) (112-116) that uses the consumable part. Upon successful verification, the consumable part 122 is moved to the loadlock 110 for onward transmission to the process module 112-116. In addition to verifying the consumable part 122, the software 126 may also issue commands to the processor 128. Responsive to the commands from the software 126 of the controller 108, software deployed in the processor 128 causes activation/deactivation of the light source 134, adjustment to light intensity of the light source 134, activation/deactivation of camera 136, image quality enhancement of the image of the code captured by the camera 136, decoding of the captured image of the code, generation of a string identifying the consumable part 122 and communication of the string identifying the consumable part 122 to the controller 108 for verification.

It is noted that FIG. 1 is one example of a substrate processing system in which the image capture system is disposed to track and verify a consumable part used within the substrate processing system. The implementations are not restricted to the substrate processing system of FIG. 1 and that other types of substrate processing system with different configuration of the modules or with different modules may also be considered for deploying the image capture system for tracking and verifying a consumable part used within.

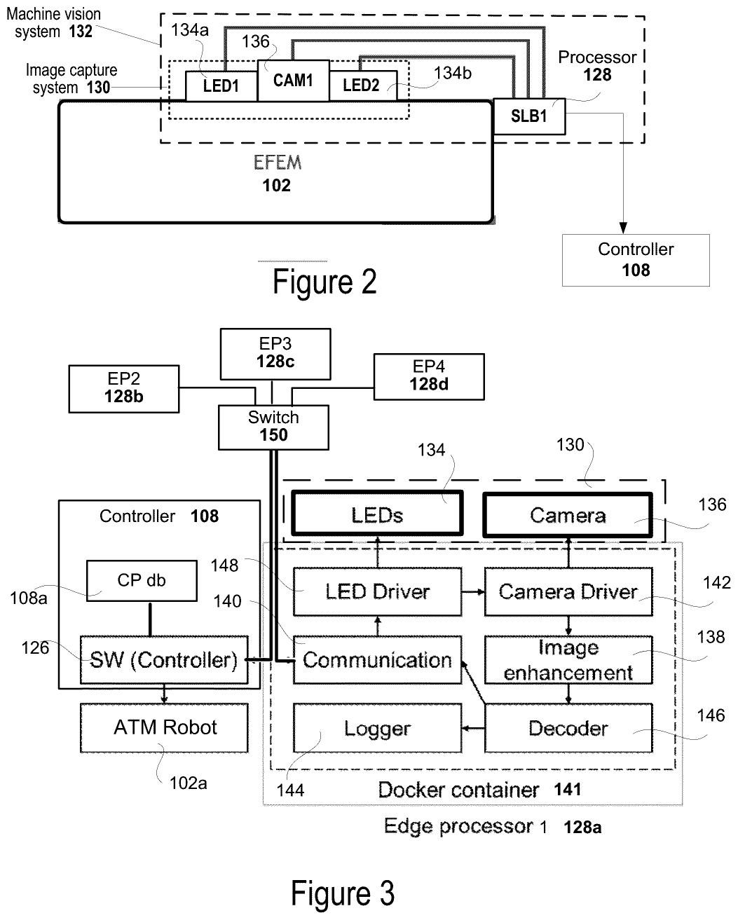

FIG. 2 illustrates a simplified block diagram of a machine vision system 132 used to track and verify a consumable part 122 prior to delivery to a process module, in one implementation. The machine vision system 132 includes an image capture system 130 and an edge computing (or edge processor) 128. The image capture system includes a camera (with lens) to capture an image of a code on the consumable part 122 and a pair of light emitting diodes (LEDs) (134a, 134b) that is used to illuminate a desired site for the camera 136 to capture an image of a subject of interest. In the present implementation, the desired site may be an area on a surface of the consumable part 122 where the subject of interest (e.g., a code, such as a QR code) 125 is defined. The number of LEDs (i.e., a pair) used to illuminate the desired site is provided as a mere example and can include additional number of LEDs, such as 3, 4, 5, 6, 8, etc. The surface of the consumable part 122 on which the code 125 is defined may be a top surface or a bottom surface. In one implementation, the consumable part 122 may be made of a transparent material and the QR code 125 may be defined on the top surface and the bottom surface with the QR code 125 on the top surface overlapping the QR code 125 on the bottom surface. The camera is powerful enough to capture the image of the QR code 125 from below.

The image capture system 130 is coupled to an edge processor 128. The image of the code captured by the image capture system 130 is forwarded to the edge processor 128. The edge processor 128 processes the code to obtain identification information of the consumable part 122 contained in the QR code 125. The identification information of the consumable part 122 is used to generate a string identifier identifying the consumable part. The string identifier is forwarded to the controller 108, which verifies the consumable part 122 and identifies the process module(s) 112-116 that use the consumable part 122. Upon successful verification, the consumable part 122 is delivered to a process module (112-116). In one implementation, in addition to verifying that the consumable part 122 is a consumable part used in a process module of the substrate processing system 100, the identification information may also be used to determine if the consumable part 122 is a new consumable part or a used consumable part and/or usage life left for the consumable part 122. Typically, the used consumable part is removed from a process module when the consumable part 122 reaches end of usage life. Therefore, performing additional verification that the consumable part retrieved from the consumable parts station 120 is new ensures that the consumable part that is slated for the process module 112-116 has sufficient usage life.

FIG. 3 illustrates a simplified block diagram showing some components of a controller 108 and of an edge processor 128 used to track the consumable part 122, in one implementation. The controller 108 and the edge processor 128 are part of a substrate processing system 100. The controller 108 includes a processor that is used to control operation of various components of the substrate processing system 100. The controller may be an independent computing device or may be part of a network of computing devices (e.g., part of a cloud system). The controller 108 is connected to the various components of the substrate processing system 100, such as atmospheric transfer module (ATM) 102, ATM robot 102a of the ATM 102, vacuum transfer module (VTM) 104, robot of the VTM 104a, loadlocks 110, process modules 112-116, isolation valves (not shown) defined at load ports 106, consumable parts station 120, wafer stations (not shown), loadlocks 110, VTM 104, etc., power source(s), chemistry source(s), etc. The controller 108 includes a software module (or simply referred to as “software”) 126 configured to provide the necessary logic to generate appropriate commands used to control operations of the various components and provide appropriate process parameters used to perform the various processes within the different process modules 112-116 of the substrate processing system 100. The software 126 is further configured to query a consumable parts database 108a available to the controller 108 to obtain details of a consumable part 122 for verifying the consumable part 122 and for identifying the process module (112-116) in which each and every consumable part 122 buffered in the consumable parts station 120 is used.

In addition to the controller 108 being connected to the various components of the substrate processing system 100, the controller 108 is also connected to the edge processor 128. In one implementation, the coupling of the edge processor 128 to the controller 108 is done via a switch 150 and such coupling may be through wired connection. For example, a first cable (e.g., a Ethernet or EtherCAT cable, or other types of cable) may be used to connect the controller 108 to the switch 150 and a second similar or different type of cable may be used to connect the switch 150 to the edge processor 128. In alternate implementations, the connection between the controller 108 and the edge processor 128 may be done through wireless connection. In some implementations, the switch 150 is coupled to a plurality of edge processors (e.g., EP1 128a EP2 128b, EP3 128c, EP4 128d, and so on) using separate cables, with each edge processor (EP1, EP2, EP3, EP4, etc.,) used to perform a different function related to the operation of the substrate processing system 100. The switch 150 acts as an Ethernet connecting the plurality of edge processors (e.g., 128a-128d) together and to the controller 108 to form a network of computing devices (e.g., local area network (LAN), wide area network (WAN), metropolitan area network (MAN), or be part of a cloud system, etc.). In some implementations, the switch 150 may connect the controller 108 and the edge processor 128 to a cloud system. One of the edge processor EP1 128a is configured to track a consumable part (122). The tracking is done by capturing an image of a code (125) disposed on the consumable part (122), process the image to decipher the code (125) to generate a string identifying the consumable part (122), and forward the generated string to the controller 108 for verification.

To facilitate capturing of the image of the code (125) on the consumable part (122), the edge processor 128 is coupled to an image capture system 130, wherein the coupling is via wired (i.e., cables) or wireless means. In some implementations, the processor (e.g., edge processor) 128 is located proximate to the image capture system 130 and the software deployed in the processor 128 is configured to receive the images of the code (125) of the different consumable parts (122) and to decipher the code captured in the images to generate strings identifying the corresponding consumable parts (122) and forwarding the string identifiers of the consumable parts (122) to the controller 108 for verification prior to forwarding the consumable part to the different process modules (112-116) for use. The edge processor(s) 128 together with the image capture system 130 constitutes the machine vision system (132).

In some implementations, in addition to coupling with the edge processor 128, the controller 108 is also coupled to the robot (also referred to herein as “ATM robot” 102a) of the EFEM (102), wherein the coupling may be via wired or wireless means. The controller 108 generates commands to control the functioning of the ATM robot 102a within the EFEM (102). Some example commands generated by the controller 108 may include a first fetch command for fetching a wafer from a wafer station and deliver to a loadlock (110) for onward transmission to a process module (112-116) for processing, a second fetch command to retrieve the processed wafer from the loadlock (110) and deliver back to the wafer station, a third fetch command for fetching a new consumable part (122) from a consumable parts station (120) and deliver to a loadlock for installing in a process module, a fourth fetch command to retrieve a used consumable part (122) from the loadlock and deliver back to the consumable parts station (120), to name a few. Of course, the aforementioned list of commands generated by the controller 108 to the ATM robot 102a is provided as a mere example and should not be considered exhaustive.

When a consumable part (122) needs to be tracked, the software 126 of the controller 108 issues a command to the ATM robot 102a within the EFEM (102) to retrieve the consumable part (122) from a slot in the consumable parts station (120) and align the consumable part (122) to a read orientation so that a code disposed on the surface of the consumable part (122) is aligned over a field of view and, in some implementations, a depth of field of an image capture system 130 disposed on an inner sidewall of the EFEM (102). In some implementations, the image capture system 130 is located near an opening of a mounting enclosure having a consumable parts station. The opening of the mounting enclosure is defined towards the EFEM (102). The opening enables a robot of the EFEM 102 to retrieve a consumable part from the consumable parts station 120. The image capture system includes a light source (e.g., LEDs 134) and the camera 136 that are oriented to point toward the opening of the mounting enclosure. The mounting enclosure with the consumable parts station (120) is disposed on an outer sidewall (also referred to as outside wall) of the EFEM (102). In some implementations, the consumable parts station (120) is disposed on the same side and above a pair of loadlocks (110) defined between the EFEM (102) and the vacuum transfer module (104) of the substrate processing system (100). In some implementations, the side on which the pair of loadlocks (110) and the consumable parts station (120) is coupled to the EFEM (not shown) is opposite to a first side where a plurality of load ports (not shown) is defined. The load ports are defined on an outer sidewall on the first side of the EFEM and are designed to receive wafer stations that are used to store wafers processed in the process module. In alternate implementations, the second side where the consumable parts station and the loadlocks are defined may be adjacent to the first side. The location of the consumable parts station (120) and hence the opening of the consumable parts station (120) to the EFEM 102 are provided as an example and are not restricted to be defined above the loadlock (110) but can be located on other sides of the EFEM (102). As a result, the location of the image capture system 130 may depend on which side of the EFEM (102) the opening of the mounting enclosure with the consumable parts station (120) is defined. Similarly, the location of the image capture system 130 is not restricted to being disposed below the opening but can be defined to be above the opening or in any other location/orientation in relation to the opening so long as the image capture system 130 is able to capture a full and clear image of the code on the consumable part (122).

Responsive to the command from the software 126, the ATM robot 102a extends an end-effector defined on the arm of the ATM robot 102a to reach through the opening and retrieve a carrier plate 162 that is housed in the consumable parts station 120, according to some implementations. The end-effector with the supported carrier plate 162 then reaches into a slot in the consumable parts station 120 and retrieves the consumable part 122 disposed thereon. In some implementations, the slot from which the consumable part is retrieved may be provided based on a signal from the controller. The ATM robot 102a then retracts the end-effector into the EFEM 102 where the consumable part 122 is aligned using an aligner (not shown) disposed on the arm of the ATM robot 102a. The alignment of the consumable part 122 is done so that the code 125 is in an open section that is not covered by any portion (including arm extensions) of the carrier plate 162. A fiducial marker 123 defined on the consumable part 122 may be used to align the consumable part 122. The fiducial marker 123 is separate from the code 125 and is defined at a predefined angle from the code 125, wherein the predefined angle may be orthogonal (i.e., +/−90°) or at 180° or anywhere in-between so long as the code is in the open section of the consumable part and is not covered by arm extensions of the carrier plate 162. The location of the code 125 in the open section allows the LEDs 134 and the camera 136 of the image capture system 130 to have an unhindered view of the code 125. The LEDs 134 are used to illuminate the code and the camera 136 of the image capture system 130 is used to capture the image of the code.

The edge processor 128 communicatively connected to the controller 108 receives the commands from the controller 108. In response to the commands from the controller 108, the different software applications deployed in the various edge processors (128a-128d) generate relevant signals to different components within or coupled to the edge processors (128a-128d) directing the components to perform the different functions and return relevant data (if any) to the controller 108. FIG. 3 shows some of the components of edge processor 128a that may be controlled by a software application deployed in the edge processor 128a for tracking the consumable part 122, in one example implementation. In an alternate implementation, the edge processor 128a may be programmed to interact with the various components and provide the necessary signals to cause the various components to perform the different functions. The components that may be controlled using the signals generated by the software application deployed in edge processor 128a or by the program defined within the edge processor 128a may include an image enhancement 138, a communication server 140, a camera driver 142, a logger 144, a decoder (e.g., QR decoder) 146 and an LED driver 148. The aforementioned list of components controlled by the edge processor 128a is provided as an example and should not be considered exhaustive. The edge processor 128a may include additional components to perform the various functions involved in tracking the consumable part 122. In some implementations, the software application deployed in the edge processor 128a is an image processing application, and the various components and their dependencies run in a container, such as a docker container 141, so the image processing application can be launched on any edge processing platform automatically and consistently.

The communication server 140 within the edge processor 128a receives the command from the software 126 of the controller 108 and forwards the command to the software application (e.g., the image processing application). The command from the controller may be to capture and provide identification information of the code 125 disposed on a surface of the consumable part 122. The command from the controller, in one implementation, may be a scan command. The scan command may be generated by the controller in response to the consumable part with the code defined on the surface having been moved to a read orientation (i.e., within a field of view of an image capture system) by the ATM robot 102a. The ATM robot 102a may have moved the consumable part to the read orientation in response to a command from the controller to the ATM robot 102a, wherein the command may have been generated automatically by the controller based on usage life left on the consumable part or based on communication from a process module in which the consumable part is deployed, or the command to the ATM robot 102a may be generated based on a command from an operator.

In response to the scan command from the controller 108, for example, the software application deployed in the edge processor 128a generates a first signal to the LED driver 148 instructing the LED driver 148 to activate a light source (e.g., pair of LEDs 134 or any other type or number of light source), and a second signal to a camera driver 142 instructing the camera driver 142 to activate the camera 136. The LEDs 134 and the camera 136 (with the lens) together represent the image capture system 130. Responsive to the signals from the software application, the light source (i.e., LEDs 134) are activated to illuminate the code and the camera is activated. The activated camera 136 captures image of the code 125 that was brought to the read orientation by the ATM robot 102a and illuminated by the LEDs 134. In the various implementations discussed herein, the code 125 is considered to be a QR code. However, the implementations are not restricted to QR code but may include other types of data matrix code, bar code, printed character code, or any other type of identification markers that can be captured in an image and discerned to obtain the identification information.

The image captured by the camera 136 captures a section of the consumable part that includes native material and the code (e.g., QR code) 125 etched/engraved/printed in the native material. In some implementations, the code 125 is etched on either the top or the bottom surface of the consumable part using a laser (e.g., laser etching). In other implementations, the code 125 may be defined using other means. In some implementations, the etched code 125 is identified by determining a contrast between the native material and the etched surface that includes the code. Determining the contrast between the etched surface and the surface with native material may be hard as the contrast is very tiny. In order to correctly decipher the code, the contrast between the etched surface and the native material surface has to be increased. To improve the contrast, the image captured by the camera is forwarded by the software application to an image enhancement module 138 for enhancing the quality of the image. The image enhancement module 138 takes the raw image provided by the camera 136, and processes the image to get rid of image noise, increase the contrast, and overall improve the quality of the image. The enhanced image from the image enhancement module 138 is forwarded by the software application to the decoder (such as QR decoder) 146 to analyze the image of the code, decipher the information contained in the image, and generate a string (i.e., string identifier) identifying the consumable part 122. It is noted that the code 125 captured in the image may be a QR code, a data matrix code, a printable character code, a bar code, etc. As a result, in one implementation, a single decoder may be configured to perform analysis of the image of any type of code 125 including the QR code to generate appropriate string identifier for the consumable part 122. In alternate implementations, the edge processor 128 may include a corresponding decoder for analyzing each type of code 125 used on the consumable part 122 and generate appropriate string identifier for the code 125. The decoder 146, as part of analysis, deciphers the details included in the image of code 125 and generates a string identifier identifying the consumable part. The string identifier generated by the decoder 146 is forwarded by the software application to the communication server 140 of the edge processor 128 for onward transmission to the controller 108 for verification. Additionally, the string identifier and the corresponding enhanced image of the code are forwarded to the logger 144 for storage. The logger 144 maintains a history of the images of the different codes captured by the image capture system, and decoded QR codes, corresponding string identifiers of the different consumable parts, consumable part errors, etc., deciphered by the decoder 146.

In one implementation, the communication server 140 forwards the string identifier with the details of the consumable part to the software 126 of the controller 108. The software 126 receives the string identifier of the consumable part, and verifies the details included in the string identifier against details of consumable parts stored in a consumable parts database 108a available to the software 126 of the controller 108. The consumable parts database 108a is a repository storing detailed information of every type of consumable part used in a fabrication facility in which the substrate processing system 100 is disposed and identity of every consumable part of each type. The verification may be to ensure that the consumable part 122 associated with the code 125 scanned and captured by the camera of the image capture system 130 is a valid one used in one or more process modules of the fabrication facility and to obtain the identity of the process modules that use the consumable part. After successful verification of the consumable part 122 retrieved from the consumable parts station 120, the software 126 may send a command to the ATM robot 102a to indicate that the verification was successful and to move the consumable part 122 to the relevant process module in which the consumable part is to be installed. If, on the other hand, the verification is unsuccessful, then an error message is generated for rendering on a display screen associated with the controller. The edge processor 128a performs the capturing and processing of the image of the code on the consumable part to generate the string identifier for the consumable part and forwards only the string identifier to the controller 108 for verification, thereby reducing or limiting the amount of data that is transmitted to the controller 108.

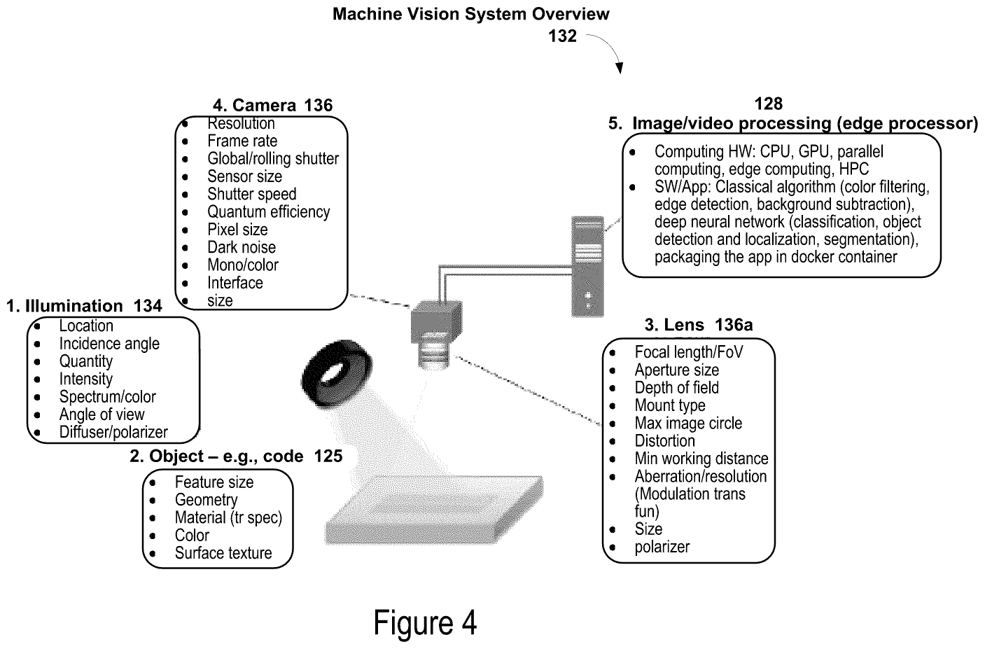

FIG. 4 illustrates the specific components of a machine vision system 132 and the various parameters associated with the specific components that have to be considered for tracking a consumable part used in the substrate processing system 100, in one implementation. In one implementation, the machine vision system 132 includes the image capture system with the camera (with the lens) 136 and light sources (e.g., LEDs) 134, and the edge processor 128. The machine vision system 132 may include additional components in addition to the image capture system and the edge processor 128. The various parameters associated with the machine vision system 132 need to be considered in order to obtain a sharp and clear image of an object of interest (e.g., code 125 (i.e., QR code)) so that the edge processor 128 can detect the finer details contained in the image and use the details to decipher the information included in the code to identify the consumable part 122. In the implementation illustrated in FIG. 4, 5 major components of the machine vision system 132 and the various parameters associated with each of the major components are shown. For example, the 5 major components of the machine vision system may include an illuminating source 134, object of interest (e.g., QR code 125), lens 136a, edge processor (used to perform image/video processing) 128, and camera 136. The aforementioned components are provided as examples and should not be considered restrictive. Fewer or greater number of components may be considered when designing the machine visions system 132. In some implementations, the lens 136a is shown separate from the camera 136. In such implementations, different lenses with different specifications, such as focal length, field of view, depth of field, resolution, etc., can be used to mount on a camera. In some implementations, the lens 136a may be part of the camera 136.

In the case of illumination source 134, some of the parameters associated with the illumination source 134 that is of relevance for capturing a clear image of the code 125 include location of the illumination source, incidence angle, quantity, intensity, spectrum/color, angle of view, diffuser and/or polarizer. In one implementation, the illuminating source is defined as a pair of LEDs. The LEDs have to be placed in locations in relation to the camera to ensure that the light from the LEDs provide optimal illumination for the region of the consumable part that includes the code in order for the camera to capture finer details of the image of the code that is shadow-free or glare-free. The shadow or glare can obscure the details of the code captured by the camera. In one implementation, a pair of LEDs is used to illuminate the code on the consumable part. Number (i.e., quantity) of LEDs is determined to ensure that the code is sufficiently illuminated. In some other implementations, instead of a pair of LEDs, a ring of small LEDs may be disposed around the camera. The implementations are not restricted to a pair or a ring of LEDs but can include additional LEDs (e.g., 4, 6, 8 etc., (i.e., more than a pair)) as needed and the various parameters that need to be considered for the pair are also relevant for the single or additional LEDs. In some implementations, the LEDs are programmable in terms of color, intensity, etc., to ensure that sufficient light is provided to illuminate the code and not too much to saturate the image.

In some implementations, the location of the LEDs within the image capture system 130, for example, includes a length of separation between the two LEDs. In addition to the length of separation of the LEDs, a height of separation (depth of field of view) of the LEDs and the camera unit from the surface of the consumable part on which the code (i.e., object of interest) 125 is also defined. In one implementation, the length of separation of the two LEDs is proportional to the height of separation of the pair of LEDs from the code. In one example implementation, the ratio is defined to be between about 1:1.3 and about 1:1.7 so as to create an overlap lighting area that covers the surface region of the consumable part where the code is disposed. In some implementations, lighting technique, such as bright field, dark field, dome light, on-axis light (DOAL), or backlight could be used depending on surface finish and transparency of the consumable part in order to distinctly identify all features of the code. It should be noted that the aforementioned lighting techniques have been provided as an example and should not be considered exhaustive and other types of lighting technique may also be engaged. The intensity of the lighting and the area of overlap of the light are defined such that the image captured by the camera includes all the finer details of the code. The incidence angle needs to be defined to provide optimal illumination of the portion of the consumable part where the code is located. With the pair of LEDs, the incidence angle may have to be defined so that a cone of light originating from one LED in the pair overlaps with the other cone of the other LED in the pair and that the area of overlap covers at least a size of the code. Number (i.e., quantity) of LEDs is determined to ensure that the area where the code is disposed on the consumable part is sufficiently illuminated. Intensity of the LEDs as well as spectrum/color also need to be considered to ensure that the portion of the consumable where the code is disposed is sufficiently lit to ensure the image is captured without any shadow or glare (or with reasonable/acceptable amount of shadow and/or glare that would not hinder the clarity of the captured image). Similarly, angle of view of the LEDs has to be considered to ensure the code is fully illuminated for the camera to capture the image. In one implementation, diffusers and/or polarizers may need to be provided to avoid glare in the image caused by the illumination provided by the LEDs in the image. In one implementation, the diffuser, when present, may be disposed in front of each LED at a predefined distance. In some implementations, in addition to or in place of the diffuser, one or more polarizers may also be provided. The polarizers, when present, may be provided in front of one or more LEDs and/or in front of lens of the camera at a predefined distance from the LEDs and/or lens.

In one implementation, the attributes and parameters related to the object of interest (i.e., code 125 (e.g., QR code)) may need to be taken into consideration when determining the various parameters of other components of the machine vision system 132. For example, the size of the code, the size of the various features within the code, geometry of the code and geometry of the features in the code will all have to be taken into consideration when determining the location of illumination, intensity of illumination, resolution of camera, etc.

Material used to make the consumable part may also need to be taken into consideration when defining various parameters of the components of the machine vision system. For instance, due to surface characteristics, different materials may reflect light differently and the image is captured based on the amount of light reflected by different portions on the surface of the consumable part. Consequently, amount of light transmitted by the different materials used for the consumable part, type of material used (i.e., transparent or opaque material), color of the material, surface finish (i.e., surface texture), etc., need to be considered when determining the features of the LEDs, the features of the camera, features of the lens, etc., that are used to capture the image of the code 125. Further, the code 125, such as the QR code, may be laser etched onto a top surface or bottom surface of the consumable part 122. Consequently, the surface characteristics of the consumable part may vary in the area where the code is defined due to the laser etching, with the portion of the surface that includes the native material exhibiting different surface characteristics (e.g., light reflectivity, light reflectance) than the portion that includes the laser etched code.

In addition to defining the code on the surface of the consumable part, a fiducial marker may also be defined on the consumable part. The fiducial marker may be an optical marker placed on the top surface or the bottom surface or both the top and the bottom surfaces of the consumable part. When the fiducial marker is on both the top and the bottom surfaces, the fiducial marker on the top surface is defined to overlap with the fiducial marker on the bottom surface. The fiducial marker is defined at a predefined distance from the code. The fiducial marker acts as a point of reference from which the location of the code can be determined. The fiducial marker may be a raised marker or an etched surface that can be detected by a sensor disposed in the arm of the ATM robot. The sensor may be a laser sensor and may be part of an aligner defined on the arm of the ATM robot. In other implementations, the sensor may be a through beam LED sensor. In one implementation, the sensor may be an analog through beam LED fiber sensor with a linear curtain head on the fibers. The aligner may be used to rotate the consumable part along an axis (e.g., horizontal axis) and the sensor used to detect the location (i.e., coordinates) of the fiducial marker in relation to a specific point on the aligner disposed on the robot arm of the ATM robot. Once the coordinates of the fiducial marker are determined, the aligner may be used to rotate the consumable part along the horizontal axis by the predefined angle either clockwise or counter-clockwise so as to position the code in line with the field of view and depth of field of the image capture system for the LEDs to illuminate the area of the consumable part that includes the code, and the camera to capture the image of the code. The code is aligned in such a manner that the code is positioned in an open area of the carrier plate on which the consumable part is received so that the camera can have an unhindered view of the code.

The various characteristics of the lens 136a used in the camera 136 may be influenced by the characteristics of the object of interest (e.g., code 125), the LEDs 134, and the camera. For example, the focal length of the lens is essential to capture the tiny features of the code (e.g., QR code). For instance, the QR code may be 3×3 mm or 4×4 mm in size and each of the elements (e.g., dots, lines, squares, rectangles, etc.,) may be about 100 microns in size, and selecting the correct focal length enables the camera to capture the tiny details of the QR code. Depth of field is also another parameter that needs to be considered when selecting the appropriate lens. For instance, when the ATM robot brings the consumable part to the image capture system, the distance at which the consumable part with the code is placed may not be 100% accurate and there might be slight variation in the aligning depth. In such cases, choosing the lens with higher depth of field can assist in capturing the image of the robot. The lens of the camera, in one implementation, may be fixed inside a housing of the image capture system using a locking ring. In alternate implementations, the lens may be designed to move up and down within the housing. In this implementation, due to limited space in the EFEM, the degree to which the lens may be allowed to move may be predefined. Mount type of the lens has to be considered when determining the lens of the camera. There are different types of mounts for the lens and choosing the right mount is crucial for the lens of the camera. For instance, some types of mounts include a C-mount, an S-mount and a CS-mount. The S-mount is for smaller sized lenses and the C-mount and the CS-mount are for large lenses. The larger lenses may provide better optical performance. In some implementations, due to space and size constraints, the S-mount may be considered for the lenses as the S-mount lenses are considerably smaller in size than the C-mount and the CS-mount lenses. An effective scan area for the lens may depend on the amount of distortion/aberration experienced in the different sections of the image, with the outer edges of the image typically experiencing higher distortion/aberration and the inner sections of the image having little distortions/aberrations. So, the selection of the lens for the camera needs to take into consideration the amount of distortion that may exist for the code, and the distortion may be based on the material of the consumable part, the type of technique used for defining the code on the consumable part, etc. The size of the lens depends on the mount type, which depends on the amount of space that is available for the image capture system within the EFEM.

Some of the characteristics that may need to be considered when selecting the camera 136 for the image capture system include resolution, sensor size, shutter speed, pixel size, dark noise, monochrome/color, size and mount, in addition to frame rate, global/rolling shutter, quantum efficiency, interface, etc. In one implementation, a camera with 1 Megapixel resolution may be selected for capturing the image of the code. In an alternate implementation, a camera with 5 Megapixel resolution may be chosen for capturing the image of the code. In one implementation, the frame rate may not be as important as the image captured is static image and not a video. In alternate implementation, the frame rate may be considered for capturing the image of the code. Similarly, global/rolling shutter may be used for capturing a moving image but since the image that is being captured is a still image, the shutter type may not be as important. In alternate implementations, global/rolling shutter may be considered as one of the parameters of the camera for capturing the image of the code.

With respect to image/video processing, the edge processor 128 is provided proximal to the image capture system of the machine vision system 132 so that the images of the code captured by the image capture system can be processed locally, the processed information used to generate a string identifying the consumable part, and providing the string identifier of the consumable part to the controller of the substrate processing system for consumable part identification. In one implementation, the edge processor 128 may be central processing unit (CPU) based. In alternate implementation, the edge processor 128 may be graphics processing unit (GPU) based. The GPU typically could process the image faster than the CPU. However, a high end CPU may process the image faster than a low end GPU. Thus, depending on the type of processing that the image needs to undergo and the processing speed of the CPU or the GPU, the edge processor may be either CPU based or GPU based. Irrespective of the processor type, the edge processor 128 is chosen to have the capability to perform parallel computing, image processing, such as color filtering, edge detection, background subtraction, contrast enhancement, binarization, morphological transformation, etc. Similarly, the software that is part of the controller is configured to receive the string identifier transmitted by the edge processor, query a consumable parts database to validate the consumable part before commanding the ATM robot to transfer the consumable part to a loadlock for onward delivery to a process module. As identified in FIG. 4, the various components are selected or are configured by taking into consideration the various parameters of the different components in order to accurately track and validate the consumable part so that only the validated consumable parts are delivered to the process modules within the substrate processing system.

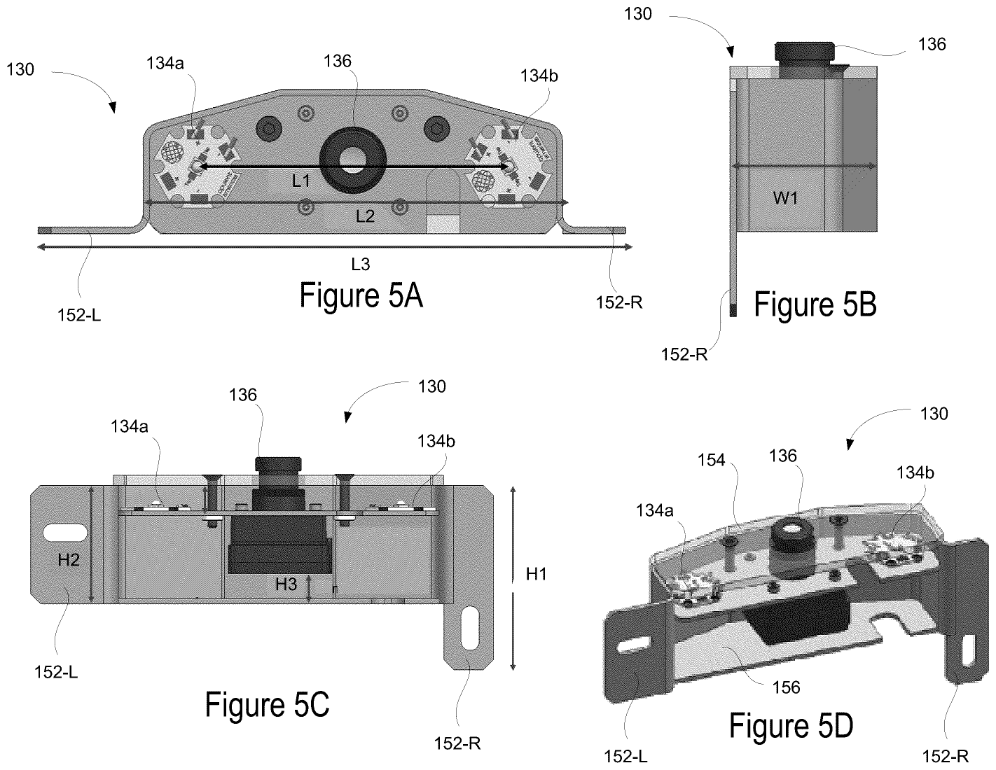

FIGS. 5A-5D illustrate the different isometric views of an image capture system 130, in some implementations. FIG. 5A illustrates a top isometric view, FIG. 5B illustrates a side isometric view, FIG. 5C illustrates a rear isometric view, and FIG. 5D illustrates a top perspective view of the image capture system 130. Referring simultaneously to FIGS. 5A-5D, the image capture system 130 includes a housing 156 (FIG. 5D) in which a camera 136 and a pair of the LEDs 134a, 134b are mounted. The housing 156 holding the camera 136 and the LEDs 134a, 134b, is attached to the inner sidewall of the EFEM using a pair of brackets. The image capture system is shown to have a pair of LEDs 134a, 134b, disposed on either side of the camera 136. The pair of LEDs (134a, 134b) are shown to be separated by a length L1. In one implementation, the length L1 is defined to be between about 70 mm and about 80 mm. The housing excluding the pair of brackets extends for a length L2. In one implementation, the length L2 is defined to be between about 90 mm and about 110 mm. The housing including the pair of brackets extends for an overall length L3. In one implementation, the length L3 is defined to be between about 130 mm and about 150 mm. The housing extends for a width W1. In one implementation, the width W1 is defined to be between about 32 mm and about 38 mm. The pair of brackets includes a left bracket 152-L and a right bracket 152-R, wherein the left and the right brackets (152-L, 152-R) each have a hole to receive a fastening/coupling means to attach the image capture system 130 to the inner sidewall of the EFEM (not shown). In one implementation, a height H1 of the right bracket 152-R is defined to be between about 50 mm and about 60 mm. A height H2 of the left bracket 152-L is defined to be between about 30 mm and about 40 mm. In one implementation, a top of the housing includes a cover 154. The cover 154 may be used to shield the LEDs and other components of the image capture system from getting exposed to any contaminants. In some implementations, the camera 136 may be disposed such that a bottom surface of the camera is separated from a bottom surface of the housing 156 by a separation distance H3 (e.g., depth of field). In one implementation, the separation distance H3 may be defined to be between about 5 mm and about 9 mm. It is understood that the dimensions provided for the various features of the image capture system 130 is provided as a mere example and that the various dimensions may vary based on the amount of space available on the sidewall below the opening of the consumable parts station to the EFEM.

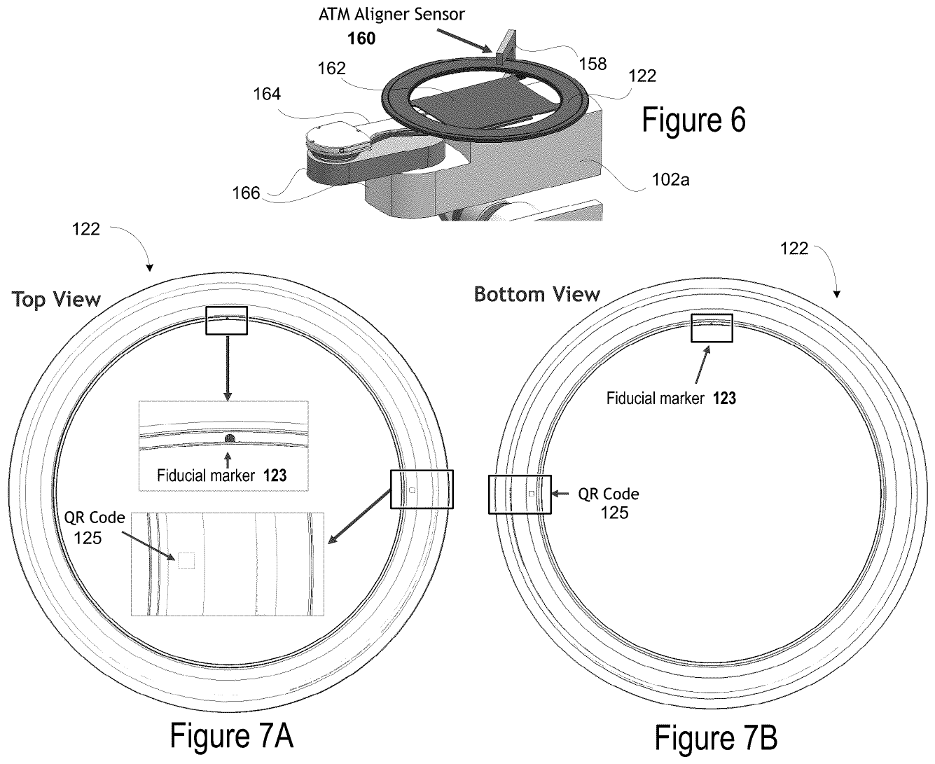

FIG. 6 illustrates a view of an arm 166 of the ATM robot 102a used to move the consumable part between the ATM and the consumable parts station, in one implementation. The arm 166 of the ATM robot 102a is shown in a folded position and is connected to the body of the ATM robot 102a on one end and to an end-effector 164 on the second end. The end-effector 164 is configured to support a carrier plate 162 and a consumable part 122 when the consumable part 122 needs to be moved between the consumable parts station and the loadlock of the substrate processing system. The end-effector 164 is also configured to support a wafer, when the wafer needs to be moved between the wafer station and the loadlock of the substrate processing system. The arm 166 of the ATM robot 102a also includes an aligner 158 that is used to rotate the consumable part 122 along an axis (e.g., horizontal axis) so that an aligner sensor 160 disposed on the aligner 158 can detect the location of a code disposed on a surface of the consumable part 122. To assist in locating the code on the surface of the consumable part 122, a fiducial marker 123 may be used. The fiducial marker 123 may be an optical marker that is different from the code 125 and defined at a predefined angle from the code 125. The end-effector brings the consumable part 122 received on the carrier plate 162 and a rotator chuck (not shown, and simply referred to as “rotator”) moves up to lift the carrier plate with the consumable part off the end-effector. Once the carrier plate is lifted up, the end-effector moves out of the way. The aligner then spins the rotator with the carrier plate while the aligner sensor 160 (e.g., a laser sensor) detects the fiducial marker 123 defined on the consumable part as the fiducial marker passes below the aligner sensor 160.

Upon detecting the fiducial marker 123, the aligner sensor 160 identifies the coordinates of the fiducial marker 123. The arm 166 of the ATM robot is provided with the offset coordinates of the code 125 in relation to the fiducial marker 123, wherein the offset coordinates are computed using the coordinates of the fiducial marker and the predefined angle of the code in relation to the fiducial marker 123. The aligner 158 then rotates the consumable part 122 along the axis either clockwise or counter-clockwise to compensate for the offset so as to line the code 125 in a position that is over a field of view of the image capture system, when the arm 166 of the ATM robot 102a is retracted out of the consumable parts station. The image of the aligned code is captured by the camera of the image capture system and used to determine the string identifier of the consumable part 122. The code 125 may be a QR code, and so, in the various implementations, the code 125 is also referred to interchangeably as a QR code 125. It should be noted that the code 125 is not restricted to QR code but can also include bar code or other types of markers to identify consumable part 122.

FIGS. 7A and 7B illustrate some examples of the location of the code 125 in relation to the fiducial marker 123 defined on the surface of the consumable part. FIG. 7A illustrates a top view of the consumable part 122 with the fiducial marker 123 and the code 125 defined on a top surface, in one implementation. It should be noted that the surface(s) where the fiducial marker is defined may be based on the type of material used for the consumable part. In some implementations, when the consumable part is made of a transparent material (e.g., quartz), the top and bottom surface have sufficient texture to disperse the light of the LEDs. In such implementations, the fiducial marker may be defined on both the bottom and the top surfaces using laser polish, such that the fiducial marker defined on the top surface overlaps the fiducial marker defined on the bottom surface. Such dual surface etching may be to ensure that the fiducial marker can be sufficiently detected. When the consumable part has flame polish on the top surface, the fiducial marker is defined on the bottom surface (since the top surface is already polished). The surface where the fiducial marker is defined is determined to ensure that the fiducial marker can be distinguished from the native surface. The code 125 is shown to be defined orthogonal to the fiducial marker 123 in a clockwise direction. An expanded view of a portion of the consumable part 122 is shown in the center of FIG. 7A to illustrate a relative size of the fiducial marker 123 and the code (e.g., QR code) 125 defined on the top surface of the consumable part. FIG. 7B illustrates a bottom view of the consumable part 122 showing the relative position of the QR code 125 to the fiducial marker 123, in another implementation. In this implementation, the QR code 125 is defined orthogonal to the fiducial marker 123 in a counter-clockwise direction. The aligner is used to align the QR code 125 based on the detected fiducial marker 123 so that the QR code 125 aligns within the field of view of the camera of the image capture system.

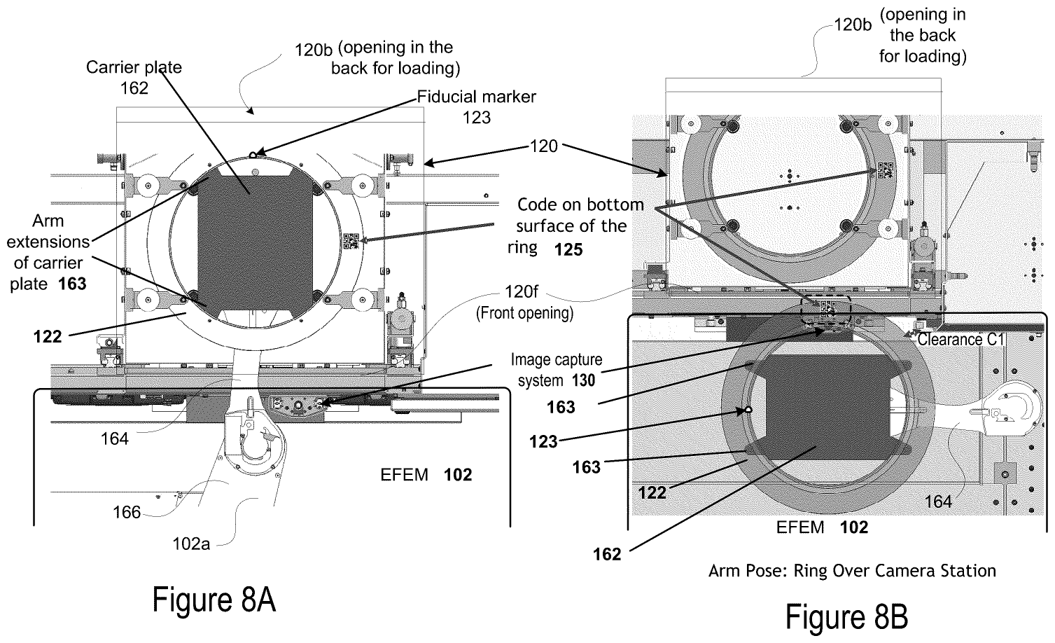

FIGS. 8A and 8B illustrate the retrieval of the consumable part 122 from the consumable parts station 120 to the EFEM 102 and positioning of the code on the consumable part 122 over an image capture system 130 for verification prior to use in a process module (not shown), in one implementation. The ATM robot 102a is used to retrieve the consumable part 122 from a consumable parts station 120. In one implementation, the consumable parts station 120 provides housing (i.e., buffer) for a plurality of consumable parts and includes a plurality of slots disposed in a vertical orientation for receiving the consumable parts 122. A separate housing is provided for a carrier plate 162. The housing for the carrier plate 162 may be defined on top of a bottom surface or on an underside of a top surface or on top of a separation plate defined between the top surface and the bottom surface of the consumable parts station 120. In one implementation, a controller (not shown) of the substrate processing system issues a first command to the ATM robot 102a to retrieve a consumable part 122 located in the consumable parts station 120, and a second command to an edge processor (not shown) to identify the consumable part 122. In response to the first command from the controller, the ATM robot 102a extends its arm 166 equipped with an end-effector 164 into the consumable parts station 120 via an opening on the front side 120f (i.e., the side of the consumable parts station 120 that is coupled to the EFEM 102 at the opening) to retrieve a consumable part from a slot. The ATM robot 102a first retrieves the carrier plate 162 from the carrier plate housing (not shown) and then moves to the slot in the consumable parts station 120 to retrieve the consumable part 122 received therein. A plurality of consumable parts is loaded manually into the consumable parts station 120 from an opening 120b in an outside wall defined in the back so that the fiducial markers 123 defined on the consumable parts 122 all align with one another and to a specific marker defined on the consumable parts station 120. In one implementation, the consumable parts 122 are loaded to orient the fiducial markers 123 to align with a center of a transparent window defined in the top surface of the consumable parts station 120. The code (e.g., QR code) 125 is shown to be disposed orthogonal to the fiducial marker 123 in a clockwise direction. The retrieved consumable part is then aligned in relation to the image capture system 130. Further, the aligning of the consumable parts 122 is done so that the fiducial marker 123 and the QR code 125 are outside an area covered by the arm extensions 163 of the carrier plate 162. Such aligning is to make sure that the QR code 125 is visible to the camera and is not obstructed by any portion of the carrier plate 162. In the implementation illustrated in FIGS. 8A and 8B, the size of the fiducial marker 123 and the QR code 125 are exaggerated for illustration purposes, whereas in reality the size is much smaller (e.g., about 80-120 microns in size).

The consumable part 122 is retrieved from the slot and balanced on the end-effector 164. The end-effector 164 with the consumable part 122 on the carrier plate 162 is then retracted from the consumable parts station 120 so that the consumable part 122 is brought into the EFEM 102. While in the EFEM 102, the aligner 158 (of FIG. 6) disposed on the arm 166 of the ATM robot 102a is used to align the consumable part 122 so that when the consumable part 122 is positioned over the image capture system 130, the QR code 125 of the consumable part 122 aligns in the field of view and depth of the field of the camera (i.e., read position) of the image capture system 130. FIG. 8B shows the QR code 125 being aligned in the field of view defined over the camera of the image capture system 130 as the arm 166 with the end-effector 164 positions the aligned consumable part 122 in a read position over the image capture system 130.

Upon detecting the consumable part positioned over the image capture system 130 (e.g., the controller may receive signal from one or more sensors positioned near or at the opening a and/or in the image capture system 130), the controller issues a second command to the edge controller to capture the image of the QR code 125. In response to the second command, the edge controller issues a first signal to the LED driver to activate the LEDs and a second signal to a camera driver to activate the camera. Responsive to the first signal, the LED driver turns on the LEDs to illuminate the area of the consumable part with the QR code 125 aligned over the LEDs. Similarly, responsive to the second signal, the camera driver turns on the camera to capture the image of the area where the QR code 125 is present.

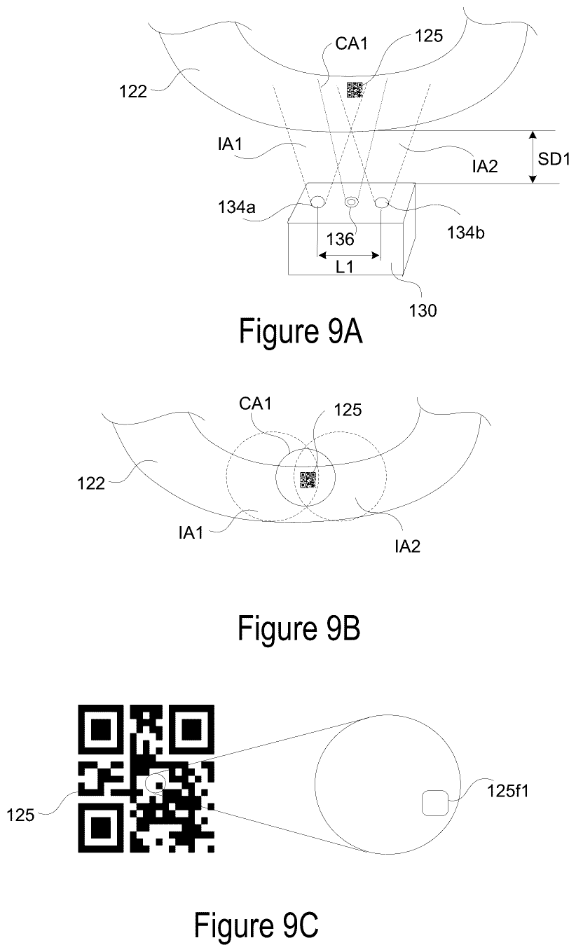

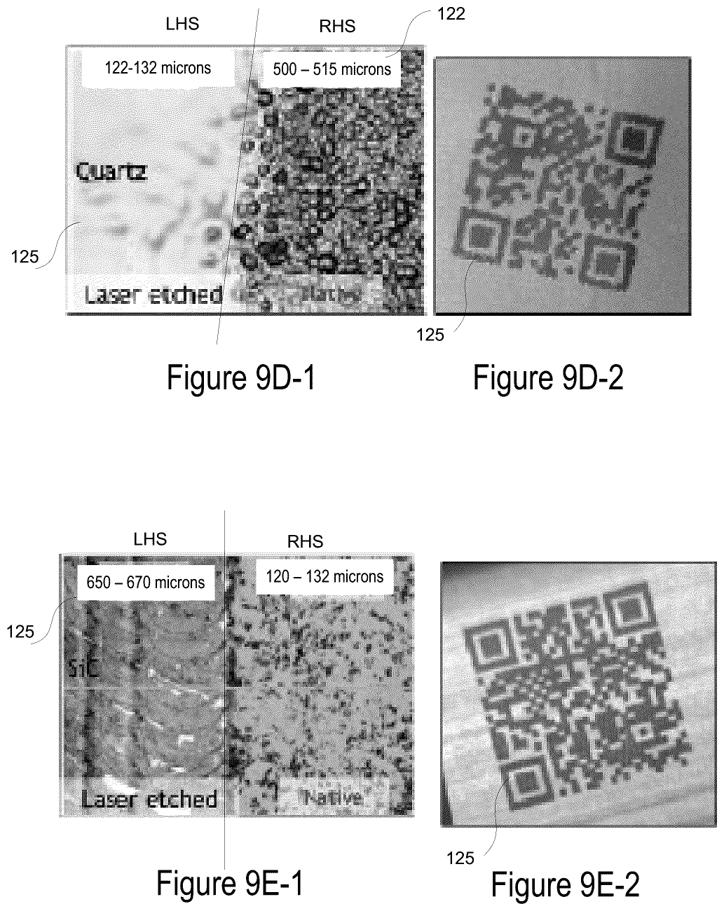

FIGS. 9A-9C illustrate the areas illuminated by the pairs of LEDs and the field of view of the lens of the camera 136, in one implementation. FIG. 9A illustrates an isometric view of a portion of the consumable part with the QR code 125 aligned over the image capture system 130. The LEDs 134 disposed on either side of the camera 136 illuminates the portion of the consumable part with the QR code 125 such that a portion of the cone of light (i.e., illumination area IA1) from the first LED 134a overlaps with a portion of the cone of light (i.e., illumination area IA2) from the second LED 134b. The distance of separation between the two LEDs 134a, 134b is defined by L1. The separation distance L1 between LEDs 134a, 134b is defined such that the area of overlap defined by the IA1, IA2 covers at least a size of the QR code 125. Further, the separation distance L1 is defined to ensure that the light from the LEDs is not too little to create shadow or too much to cause glare in the area of the QR code 125 that is being captured. The separation distance between the surface of the consumable part 122 where the QR code 125 is defined and the camera 136 is defined by SD1. The separation distance SD1 is proportional to L1. In some implementations, to achieve the highest effective field of view for the camera to capture the image of the QR code 125, the optimal L1 and SD1 distances may be defined to be between about 1:1.3 to about 1:1.7. When the consumable part with the QR code 125 is aligned within the field of view and the optimal depth of the field of the image capture system, the overlap area CAI covers the area where the QR code 125 is disposed. The camera 136 captures the image of the QR code 125 illuminated by the pair of LEDs (134a, 134b). FIG. 9B illustrates a two-dimensional representation of the areas illuminated by the pair of LEDs and the overlap area in relation to the QR code 125. The illumination area IA1 of LED 134a overlaps with the illumination area IA2 of LED 134b to define the coverage area CAI that covers the area where the QR code 125 is disposed.

The image captured by the camera 136 is received by the image enhancement module (138 of FIG. 3) for further enhancing. The enhanced image is forwarded to the decoder (e.g., QR decoder (136)) where it is analyzed and decoded to identify details of each and every feature of the QR code 125. The details of each and every feature of the QR code 125 are used to generate a string identifier for the consumable part. FIG. 9C illustrates an example of a feature 125f1 that is identified from the enhanced image of the QR code 125. As can be seen from the enlarged image of the QR code 125, the QR code 125 includes a plurality of features, wherein the features are of different shapes and sizes. The shapes and sizes of the features can be interpreted to identify different details of the QR code 125. The details of the QR code 125 are used to generate a string identifying the consumable part. FIGS. 9D-1 through 9E-2 illustrate surface characteristics of a QR code 125 etched on a surface of a consumable part 122, in some implementations. FIG. 9D-1 illustrates the surface characteristics of a portion of the consumable part made of Quartz material where a QR code 125 shown in FIG. 9D-2 is laser etched on one surface, in one implementation. FIG. 9E-1 illustrates the surface characteristics of a portion of the consumable part made of Silicon Carbide material where the QR code 125 of FIG. 9E-2 is laser etched on the surface of the consumable part 122, in an alternate implementation. The left hand side (LHS) of FIG. 9D-1 shows the laser-etched surface while the right hand side (RHS) of FIG. 9D-1 shows the native material (i.e., Quartz material). The laser-etched surface is smooth whereas the surface that is not laser-etched (i.e., has native material) has surface characteristics (i.e., rough). Due to the variance in the surface texture, the incidental light from the LEDs 134 may be reflected differently.

The variance in the surface texture (i.e., relative roughness) between the etched and the non-etched surface may be in micron range. The variance in the light reflection from the different surface is captured by the camera, wherein the reflection in the light is lot more in the section of the native material where the surface is rough (i.e, has texture) than in the section that was laser etched to define the QR code 125. The image of the different sections is enhanced using the image enhancement module 138 and used in identifying different features, including feature 125f1 (shown in FIG. 9C), which can be few microns in size. The LHS of FIG. 9E-1 shows the laser-etched surface while the RHS of FIG. 9E-2 shows the native material. The surface texture of the etched surface of the consumable part 122 made of Silicon Carbide material is different from the surface texture of the etched surface of the consumable part made of Quartz material and the camera is able to capture the variation in the light reflection from the different surfaces. The different modules of the edge processor are used to enhance the image, analyze the image to identify the features based on the material used in the consumable part and the type of technique used to define the code on the surface of the consumable part. The various features of the QR code 125 are combined to determine the details of the consumable part 122, which is used to define a string identifying the consumable part. The string identifier of the consumable part is forwarded to the controller for verification. Once the consumable part 122 is verified as a valid consumable part that is to be used in a particular process module within the substrate processing system, the controller then issues a command to the ATM robot to transport the consumable part to the loadlock for onward transmission to the particular process module for installation.

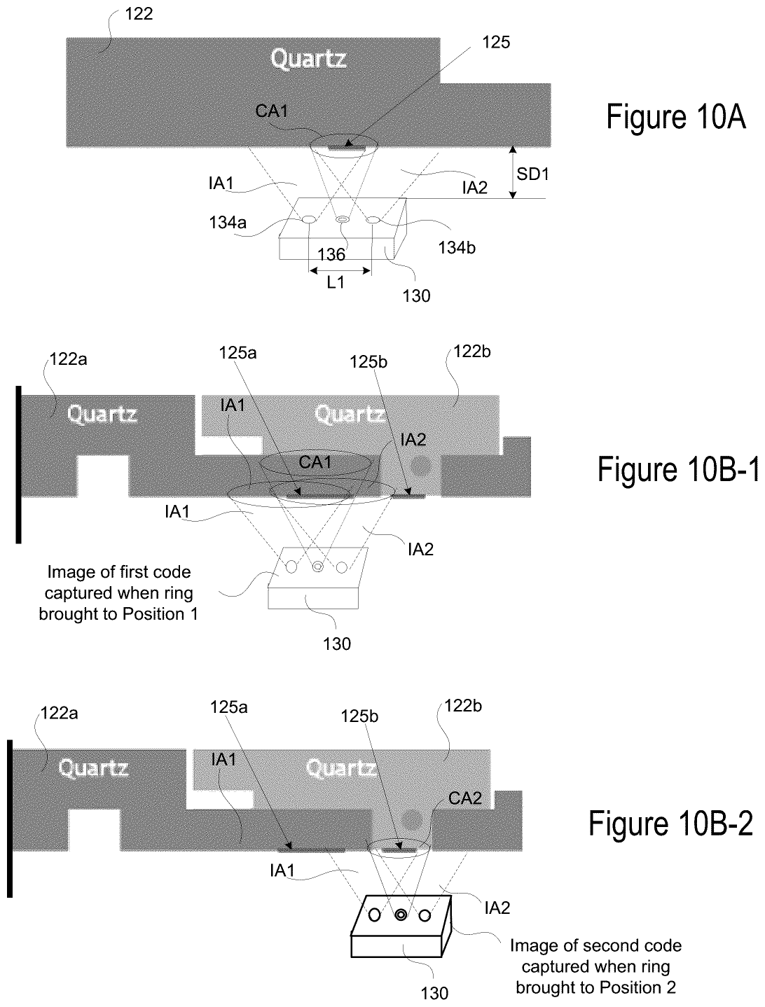

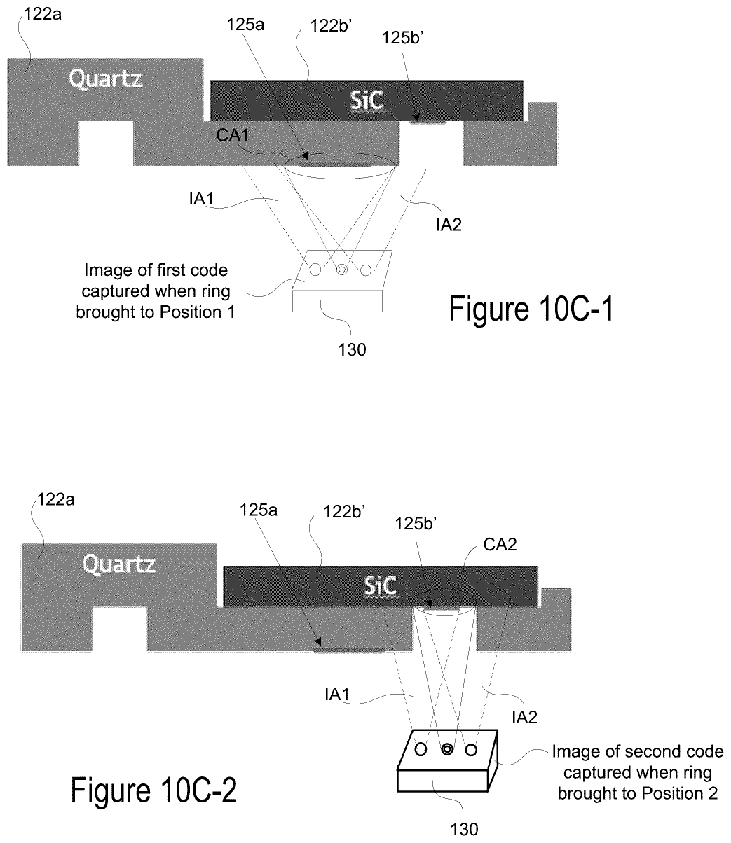

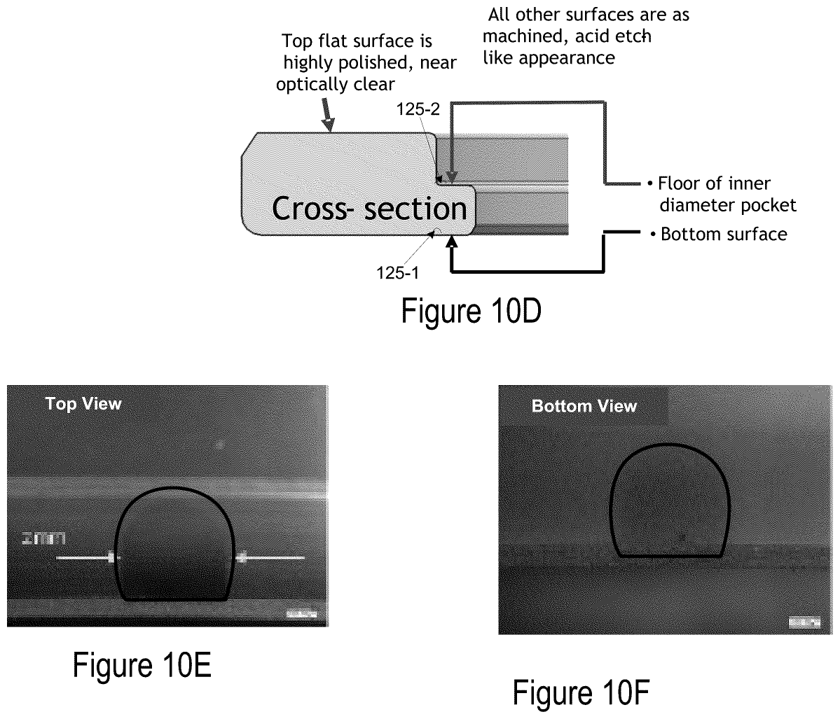

FIGS. 10A-10C illustrate different designs of a consumable part, such as an edge ring, that may be used in a process module within a substrate processing system, in some implementations. The consumable part, such as an edge ring, may be a single ring or may be a set of rings. In the case of the set of rings, the rings may be interlocking with one another or may be stacked one on top of another. Each ring in the set of rings may be made of a single material or of different materials. Depending on the type of material used for the consumable part, the code is defined on both the rings either on the bottom surface, or the top surface, or on both the top and the bottom surfaces with the code on the top surface overlapping the code on the bottom surface. FIG. 10A illustrates a consumable part 122, which is a one piece consumable part made of Quartz material, in one implementation. The QR code 125 for the consumable part 122 may be defined on a top surface or a bottom surface or both the top and the bottom surfaces. In FIG. 10A, the QR code 125 is defined on the bottom surface of the consumable part 122. When aligned by the aligner of the ATM robot, the QR code 125 is oriented such that the QR code falls in the overlap area shown as CAI in FIG. 10A. The overlap area CAI is defined from the illumination area IA1 of LED 134a and illumination area IA2 of LED 134b. The overlap area CAI provides sufficient illumination to allow the camera 136 of the image capture system 130 to capture the image of the QR code 125 but not too much light to cause glare or too little light to cause shadow. The material used for making the consumable part is not restricted to Quartz but could be Silicon Carbide or other similar material.

FIGS. 10B-1 and 10B-2 illustrate an alternate implementation in which the consumable part is made of a pair of rings, wherein the rings are interlocking with one another. Each ring of the pair of rings is made of same material (e.g., Quartz) and has a separate code disposed on the surface of the respective ring. The code on each ring is defined at different location. In the implementation of FIG. 10B, the interlocking of the rings results in the top surface of the first ring 122a to be co-planar with the top surface of the second ring 122b. A first code 125a of the first ring 122a and a second code 125b of the second ring 122b are defined on the bottom surface of the first and second rings, respectively. In this implementation, the ATM robot is instructed to read the first and the second codes 125a, 125b, separately. Consequently, the ATM robot receives a first instruction to bring the first code 125a of the first ring 122a to align within the field of view of the camera, as shown in FIG. 10B-1, and a second instruction to move the consumable part either clockwise or counter-clockwise so as to align the second code 125b of the second ring 122b with the camera. In the example illustrated in FIG. 10B-2, the second instruction is to move the consumable part in a clockwise direction for a length driven by the separation distance between the first and the second codes. To assist the ATM robot with the alignment, the coordinates of the first code 125a of the first ring 122a and the second code 125b of the second ring 122b are provided by the controller via the edge processor. Similarly, a first instruction (i.e., command) is provided to the edge computer to activate the LEDs to illuminate the area of the consumable part with the first code 125a and to activate the camera to capture the image of the first code 125a of the first ring 122a, and a second instruction to activate the LEDs to illuminate the area of the second code 125b of the second ring 122b and to activate the camera to capture the image of the second code 125b. In some implementations, once the camera captures the image of the first code 125a, the camera and the LEDs are deactivated and are re-activated by the second instruction. The LEDs are therefore used to illuminate the area around one code at a time and are not used to illuminate both the codes at the same time. Further, the LEDs illuminate the code tangentially to prevent casting of any shadows.

FIGS. 10C-1 and 10C-2 illustrate another alternate implementation where the consumable part is made of two pieces (i.e., a pair of edge rings). Further, each piece (i.e., each ring) of the pair is made of different material. For instance, the first ring (i.e., first piece) 122a is made of Quartz material and the second ring (i.e., second piece) 122b is made of Silicon Carbide. Further, the second ring 122b is stacked on top of the first ring 122a. As a result, the first code 125a of the first ring 122a is disposed at a different depth than the second code 125b′ of the second ring 122b′, and both the codes are defined on the bottom surface of each ring (122a, 122b′). As with the implementation defined with reference to FIGS. 10B-1, 10B-2, the ATM robot is provided with the coordinates of the two codes 125a, 125b′ to assist the ATM robot to align the two codes separately within the field of view of the camera of the image capture system. In addition to providing the coordinates, the ATM robot may also be provided with depth details of the two codes 125a, 125b′, to allow the camera to capture the images of the two codes sequentially. As with the implementation of FIGS. 10B-1, 10B-2, the ATM robot aligns the first code 125a of the first ring 122a to be within the field of view of the camera of the image capture system and the LEDs and the camera are both activated, in response to instructions from the controller via the edge processor. The camera captures the image of the first code 125a as shown in FIG. 10C-1. Once the image of the first code 125a is captured, a second command from the controller causes the ATM robot to align the second code 125b′ of the second ring 122b′ to be within the field of view of the camera of the image capture system and the LEDs and the camera are both activated to allow the camera to capture the image of the second code 125b′, as shown in FIG. 10C-2. One difference between FIGS. 10B-2 and 10C-2 is that the depth of the field of the camera and the illumination area of the LEDs are further in FIG. 10C-2 than in FIG. 10B-2 and this is due to the differences in the depths of the codes 125b and 125b′. The lens used in the camera is selected so as to be able to capture the image of the first code at the first depth and the second code at the second depth.

FIG. 10D illustrates a cross-sectional view of a consumable part (e.g., edge ring) with a pocket defined at an inner diameter, in one implementation. In this implementation, the top surface of the consumable part is highly polished (i.e., nearly optically clean surface). Consequently, the code has to be defined on a different surface than the top surface. This is because due to the high polish, the reflectivity of the top surface is low. When the code is defined on such highly polished surface, the variance in the reflectivity of the section of the consumable part with the code and the section without the code may be very minimal. To ensure that the image of the code can be properly captured and read, the code is defined on either the bottom surface (125-1) or on the floor at the inner diameter of the pocket (125-2). The code defined on such surfaces can be easily determined based on the variance in the reflectivity of the light from such surfaces. In some implementations, the inner diameter pocket is defined in the consumable part to provide support to a wafer, when the wafer is received in the process module with the consumable part. The aligner used to align the consumable part is also used to align the wafer, when received in the substrate processing system. In the case of the consumable part, the aligner is configured to detect the fiducial marker. In the case of the wafer, the aligner may be configured to detect a notch in the wafer so as to align the wafer before the wafer is delivered to the process module. The fiducial marker is detected on the consumable part before the wafer is received on the consumable part. Further, in some implementations, aligning the consumable part for delivery to the process module includes aligning the fiducial marker of the consumable part with the notch of the wafer.

FIGS. 10E and 10F illustrate the orientation of the fiducial marker in relation to the code, in some implementations. FIG. 10E shows a top view of the fiducial marker defined on the consumable part and FIG. 10F shows a bottom view. As shown from the image captured in the FIGS. 10E and 10F, the fiducial marker is more distinctly detected when the fiducial marker is made on the top surface of the consumable part rather than the bottom surface. Further, the marker on the top surface provides visibility to the operators during manual loading and unloading from the consumable parts station, so that the consumable parts within the consumable parts station are properly aligned. In the top view of FIG. 10E, a shadow region is shown where the fiducial marker is defined. The shadow region shown in the top view extends to only a certain depth of the consumable part, wherein the shadow region may be used as an indicator of the presence of a fiducial marker. The fiducial marker may be defined as an etched out portion, wherein the portion is not etched all the way through the depth of the consumable part. The bottom view also shows the shadow. However, the intensity of the shadow in the bottom view is less than the intensity of the shadow show in the top view. The smaller intensity of the shadow may be due to the fact that the fiducial marker has not been defined completely through the depth of the consumable part. In some implementations, the sensor of the aligner, in one implementation, is a through-beam LED fiber sensor with a linear curtain head on the fibers or a simple laser sensor that is capable of detecting the intensity of the shadow to determine where the fiducial marker is defined on the consumable part. In the region where the fiducial marker is present, more light is transmitted through than the region where no fiducial marker is present. The aligner sensor is able to detect this variance and associate this variance to the presence of the fiducial marker. Upon detecting the presence of the fiducial marker, the ATM robot associates the coordinates to the fiducial marker. The coordinates of the fiducial marker are in relation to a reference point on the aligner. The coordinates of the fiducial marker are then used in determining the location of the code and is also used in aligning the consumable part when the consumable part is delivered to a process module for installation. The detection of the fiducial marker on the consumable part is done in a manner similar to the detection of a notch on the wafer used in the process modules.

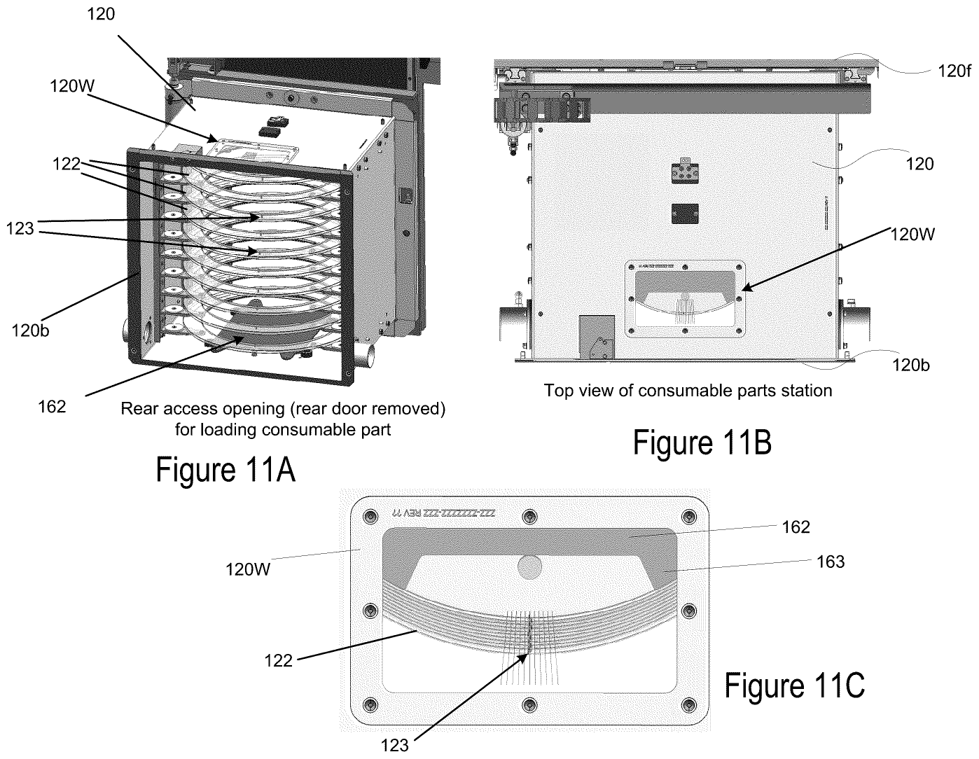

FIGS. 11A-11C illustrate a consumable parts station that is used to buffer consumable parts used in the different process modules of the substrate processing system. The consumable parts station 120 includes an opening on the front side 120f that opens into the EFEM. The consumable parts station 120 may be coupled to an outer sidewall of the EFEM on a side where a pair of loadlocks is defined. In some implementations, the loadlocks are defined between the EFEM and the vacuum transfer module. In one implementation, the sidewall where the EFEM and the loadlocks are defined may be opposite to a second side where a set of loadports are defined. The loadports are defined on an outer sidewall of the second side. The loadports are configured to receive wafer stations that are used to buffer wafers processed in the process modules of the substrate processing system, and include openings to allow movement of the wafers into and out of the wafer stations. In alternate implementations, the consumable parts station may be defined on a side that is adjacent to the side where the loadlocks are defined or where the wafer stations are defined. in some implementations, the consumable parts station includes a plurality of slots defined in a vertical orientation that are configured to receive and buffer consumable parts used in the process modules. In some implementations, the consumable parts station also houses a carrier plate 162 used to support the consumable part when the consumable part needs to be moved between the consumable parts station and the process module. The carrier plate may be housed on the bottom surface or on the underside of the top surface or on a separation plate defined between the top surface and the bottom surface. The consumable parts station also includes a second opening defined in the outside wall (i.e., the sidewall defined in the back side) for loading the consumable parts into the consumable parts station. FIG. 11A shows an isometric view of the insides of the consumable parts station 120 with the back door removed to show the second opening. The consumable parts station 120 also includes a transparent or see-through window 120W on the top surface to provide a view into the insides of the consumable parts station 120. In one implementation, the transparent window 120W is made of plexiglass. In one implementation, the consumable parts are loaded into the consumable parts station 120 such that the fiducial markers are aligned in the back of the consumable parts station so as to be within a tolerance range (e.g., +/−5°) so that the aligner on the ATM robot can take care of the finer alignment. When the consumable part is to be moved out of the consumable parts station by the ATM robot, the ATM robot reaches through the front opening (not shown) of the consumable parts station 120 and moves the consumable parts 122 supported on the carrier plate 162 out of the consumable parts station and into the EFEM. The front opening is designed so that there is sufficient clearance between the edge of the front opening and the consumable part 122 as it is being moved out of the consumable parts station 120. In some implementation, the clearance is between about 3 mm and about 7 mm. In alternate implementations, the clearance may be smaller or greater than the aforementioned range.

FIG. 11B shows an overhead view of the top surface of the consumable parts station 120, in one implementation. Top surface shows a transparent (i.e., see-through) window 120W defined proximate to the back opening (i.e., second opening defined in the outside wall defined in the back of the consumable parts station 120) 120b that is used for loading and unloading the consumable parts into and out of the consumable parts station. The window 120W acts as a peep window providing a view of the inside of the consumable parts station 120. The consumable parts are loaded so that the fiducial markers align in the back and to the center of the window 120W. During loading (e.g., manual loading or machine loading), the fiducial markers 123 of the consumable parts may not all align precisely and there may be alignment offset from a desired location. FIG. 11C shows an angled view looking down on a stack of 10 consumable parts (e.g., edge rings) received in the consumable parts station. The consumable parts are aligned so that the fiducial markers 123 of the various consumable parts are within an acceptable alignment offset tolerance, when the consumable parts are loaded into the consumable parts station. In one implementation, the acceptable tolerance of alignment offset can be +/−5° from the center of the window 120W. The acceptable alignment offset tolerance limit is provided as an example and other range may also be considered. Maintaining the alignment of the consumable part during loading assists in faster alignment of the code over the image capture system, when the consumable part is moved over the image capture system.

Faster alignment results in faster capture and process of the image and faster identification and verification of the consumable part.

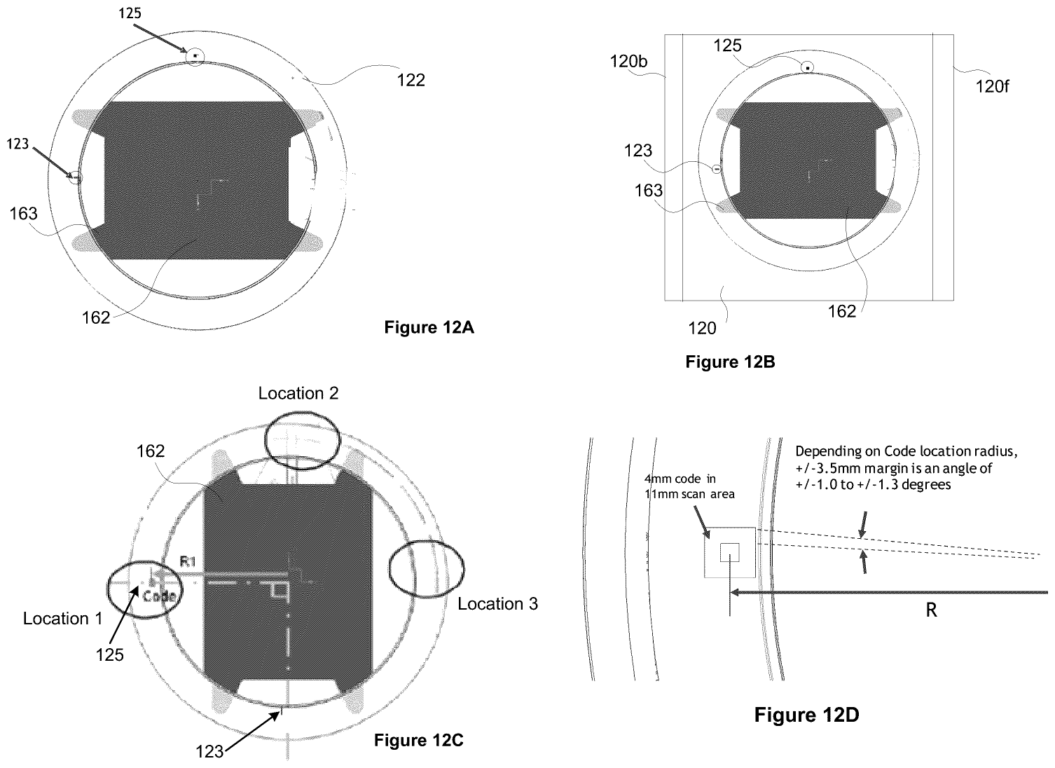

FIGS. 12A-12D illustrate the alignment of the fiducial marker in relation to the code on the consumable part and in relation to the consumable parts station, in some implementations. The fiducial marker is aligned to be outside of the area of the consumable part that is covered by the carrier plate 162 and arm extensions of the carrier plate 162. As noted with reference to FIGS. 11A-11C, when loading the consumable parts into the consumable parts station, the consumable parts are aligned so that the fiducial markers are aligned in relation to a predefined location defined in the back of the consumable parts station. In some instances, the consumable parts may not all align with the predefined location but may be offset within a tolerance limit (e.g., +/−5°). FIG. 12A illustrates an overhead view of the consumable part received over a carrier plate 162, which is supported on the end-effector (not shown) of the ATM robot. FIG. 12A also shows the location of the fiducial marker 123 and location of the code 125 in relation to the fiducial marker 123, in one implementation. The code 125, in this implementation, is defined orthogonal (i.e., 90°) to the fiducial marker 123 in a clockwise direction. The consumable part is aligned so that both the code and the fiducial marker are in areas that are not covered by any parts of the carrier plate 162 including the arm extensions 163, thereby providing clear view of the code to the camera for capturing the image of the code. FIG. 12B illustrates the relative orientation of the fiduciary marker within the consumable parts station 120. As noted, the fiduciary marker aligns to the back of the consumable parts station 120 and is aligned to be outside of the area where the arm extensions 163 of the carrier plate 162 are located. FIG. 12C illustrates the alternative locations of the code 125 on the consumable part 122 in relation to the fiducial marker 123. The code 125 may be oriented orthogonal to the fiducial marker 123 in a clockwise (location 1) or counter-clockwise (location 3) direction or may be oriented straight across (location 2) from the fiducial marker. In some implementations, the code 125 may be oriented from the fiducial marker by predefined radial degrees (e.g., 90°, 180°, 270°, etc.) in the clockwise or counter-clockwise direction. In some implementations, the code 125 is not oriented orthogonal or straight across but is disposed at an angle that the code 125 and the fiducial marker 123 are in a region of the consumable part 122 that is not obscured by any part of the carrier plate 162. FIG. 12D illustrates the scan area (i.e., field of view) of the camera of the image capture system when capturing the image of the code 125. The QR code 125 can be small (e.g., about 3-5 mm) in size and therefore needs to be captured with high precision to capture the details of the QR code 125. As a result, the camera is configured to capture the details on the surface of a portion of the consumable part that includes the QR code. In the implementation illustrated in FIG. 12D, depending on the QR code location radius, the camera captures a scan area of about +/−1° to about +/−1.3°, which translates to about +/−3.5 mm margin from the edge of the QR code. For example, if the size of the QR code 125 is about 4 mm square, then the scan area captured in the image may encompass +/−3.5 mm for a total scan area of about 11 mm. FIG. 12D shows the area covered by the QR code 125 and the scan area surrounding the QR code 125. Thus, based on the location of the QR code 125 on the consumable part, the image of the QR code captured by the camera not only includes the area of the QR code but also the area surrounding the QR code area. The features of the QR code can be determined by detecting the difference in the surface characteristics of the different portions of the scan area.

The various implementations described herein provide a way to track and verify a consumable part prior to transporting to a process module. The verification avoids getting a wrong consumable part into a process module or delivering a consumable part to a wrong process module. The in-line camera system (i.e., the image capture system) that is part of the substrate processing system is able to capture image of QR code defined on the surface of the consumable part irrespective of the material used, number of pieces that make up the consumable part, size and geometry of the code defined thereon, etc. The various implementations are discussed with reference to the code being a QR code but can be extended to other types of codes (e.g., bar code, other data matrix code).

The foregoing description of the various implementations has been provided for purposes of illustration and description. It is not intended to be exhaustive or to limit the invention. Individual elements or features of a particular implementation are generally not limited to that particular implementation, but, where applicable, are interchangeable and can be used in a selected implementation, even if not specifically shown or described. The same may also be varied in many ways. Such variations are not to be regarded as a departure from the invention, and all such modifications are intended to be included within the scope of the invention.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. A machine vision system for tracking and verifying a consumable part in a substrate processing system, comprising:
a mounting enclosure with a consumable parts station for storing consumable parts within, the mounting enclosure has an opening towards an equipment front end module (EFEM) of the substrate processing system to enable a robot in the EFEM to retrieve a consumable part from the consumable parts station;
an image capture system configured to capture an image of a code on the consumable part, the image capture system including a camera and a light source, the image capture system is positioned near the opening of the mounting enclosure, wherein said camera and the light source are oriented to point toward the opening of the mounting enclosure;
a processor communicatively connected to the image capture system and a controller, the processor is configured to process and analyze the image of the code captured by the image capture system and generate an identifier for the consumable part that is returned to the controller; and
the controller configured to cause the robot to move the consumable part from the consumable parts station via the opening of the mounting enclosure and to position the code of the consumable part within a field of view of the image capture system, and in response to the identifier provided by the processor, verify that the consumable part is suitable for a subsequent operation.

2. The machine vision system of claim 1, wherein the processor is configured to interact with,
an image enhancement module to enhance the image,
a decoder to decode an enhanced image and generate a string identifying the consumable part;
a communication module to communicate the string identifying the consumable part to the controller for verification.

3. The machine vision system of claim 2, wherein the controller is configured to,
provide signals to the processor to activate the light source and initiate capture of the image of the code; and
verify the consumable part using the string forwarded by the processor.

4. The machine vision system of claim 1, wherein the light source includes a plurality of light elements, location of the plurality of light elements is defined to illuminate the code and to provide an overlapping region that at least covers an area on the surface of the consumable part where the code is present when the consumable part is positioned in a read orientation.

5. The machine vision system of claim 4, wherein the robot includes an aligner used to align the consumable part to the read orientation.

6. The machine vision system of claim 5, wherein the aligner is configured to detect a fiducial marker disposed on the consumable part, wherein the fiducial marker is disposed at a predefined angle from the code of the consumable part, and wherein the robot is caused to move the consumable part based on instructions from the controller, the instructions specifying the predefined angle to move the consumable part in relation to the fiducial marker so as to align the code within the field of view of the camera of the image capture system for capturing the image of the code illuminated by the light source.

7. The machine vision system of claim 4, wherein the read orientation is defined to correspond with an open region of the consumable part that is not covered by an end-effector of the robot so as to provide an unhindered view of the code for the camera for capturing the image.

8. The machine vision system of claim 1, wherein the image capture system includes a transparent cover defined in a top portion facing the opening of the mounting enclosure, the transparent cover configured to shield the camera and the light source of the image capture system.

9. The machine vision system of claim 1, wherein the camera of the image capture system is disposed at a first distance from the surface of the consumable part on which the code is disposed, and the light source includes a plurality of light elements, wherein each light element of the plurality of light elements is separated from another light element by a second distance.

10. The machine vision system of claim 9, wherein the first distance is proportional to the second distance and is defined to be between about 1:1.3 and about 1:1.7.

11. The machine vision system of claim 1, wherein the image capture system includes diffusers, or polarizers, or both diffusers and polarizers,
wherein the light source is a pair of light emitting diodes, and
wherein each diffuser, when present, is disposed in front of one or both of the pair of light emitting diodes at a predefined first distance, and
wherein each polarizer, when present, is disposed in front of one or both of the pair of light emitting diodes at a predefined second distance, or in front of lens of the camera at a predefined third distance, or in front of both the lens of the camera at the predefined second distance and one or more both of the light emitting diodes at the predefined third distance.

12. The machine vision system of claim 1, wherein the consumable parts station has an outside wall that is oriented opposite to the opening of the mounting enclosure, the outside wall has a second opening for accessing the consumable parts station for loading and unloading of the consumable parts.

13. The machine vision system of claim 1, wherein a consumable part in the consumable parts station is made of two parts and the code is disposed on a surface of each part of the two parts, wherein a first code in a first part of the two parts is separated by a predefined distance from a second code in a second part, and
wherein the robot moves the consumable part based on instructions from the controller, the instructions include a first set of instructions to move the consumable part so as to cause the first code disposed on the first part to be brought within a field of view of the image capture system and to simultaneously activate the light source to illuminate the first code and the camera to capture image of the first code, and a second set of instructions to move said consumable part so as to cause the second code disposed on the second part to be brought within the field of view of the image capture system and to simultaneously activate the light source to illuminate the second code and the camera to capture the image of the second code disposed on the second part.

14. The machine vision system of claim 13, wherein the first part and the second part of the two part consumable part is made of same material, wherein the material is one of Quartz or Silicon Carbide.

15. The machine vision system of claim 13, wherein the first part of the two part consumable part is made of different material than the second part, and wherein the first part of the two part consumable part is made of Quartz and the second part is made of Silicon Carbide.

16. The machine vision system of claim 1, wherein the light source is arranged to illuminate the code tangentially.

17. The machine vision system of claim 1, wherein the processor is an edge processor, the edge processor configured to store the image of the code, process the image, analyze the image, generate the string identifying the consumable part, and transmit the string to the controller for verification, and
wherein the edge processor is connected to the controller via an Ethernet switch.

18. The machine vision system of claim 1, wherein the consumable part is an edge ring that is disposed adjacent to a wafer received on wafer support surface within a process module of the substrate processing system.

19. A robot for tracking a consumable part in a substrate processing system, comprising:
an end-effector defined on an arm, the end-effector designed to support a carrier plate used for supporting the consumable part; and
an aligner disposed on the arm, the aligner configured to rotate the carrier plate with the consumable part along an axis, the aligner having a sensor to track a fiducial marker defined on a surface of the consumable part and provide offset coordinates of the fiducial marker to a controller of the substrate processing system,
wherein said robot is configured to receive a set of instructions from the controller to cause the robot to move the consumable part supported on the carrier plate from a consumable parts station and to a read orientation in relation to the fiducial marker, wherein the read orientation is defined to place a code disposed on the surface of the consumable part within a field of view of an image capture system of the substrate processing system to allow the image capture system to capture image of the code,
wherein the image of the code captured by the image capture system is processed to generate an identifier for the consumable part, the identifier used by the controller for verification of the consumable part.

20. The robot of claim 19, wherein the image capture system is communicatively connected to the controller, the image capture system receives a second set of instructions from the controller, wherein the second set of instructions includes a first instruction to activate a light source disposed within the image capture system to illuminate the code, and a second instruction to activate a camera within the image capture system to trigger capturing of the image of the code.

21. The robot of claim 19, wherein the fiducial marker is an optical marker defined on the surface of the consumable part at a predefined angle from the code, and
wherein the read orientation is defined to correspond with an open region of the consumable part that is outside of an area covered by arm extensions of the carrier plate.

22. The robot of claim 19, wherein the sensor of the aligner is one of a laser sensor or a through beam LED fiber sensor with a liner curtain head on the fibers.

23. The robot of claim 19, wherein the robot is disposed within an equipment front end module (EFEM) of the substrate processing system, the EFEM providing access to the consumable part stored in a consumable parts station of a mounting enclosure of the substrate processing system, the access to the consumable parts in the consumable parts station of the mounting enclosure is provided to the robot via an opening defined toward the EFEM.

24. The robot of claim 19, wherein the offset coordinates of the fiducial marker and the image of the code are forwarded by the controller to the image capture system via a processor, the processor interacts with an image enhancing module to enhance the image of the code captured by the image capture system, interacts with a decoder to decode, analyze the image and generate a string representing the identifier of the consumable part, and interacts with a communication module to communicate the string to the controller for verification of the consumable part.

25. The robot of claim 19, wherein the end-effector of the robot configured to move the consumable part from the consumable parts station is configured to move a wafer from a wafer station for delivery to a process module within the substrate processing system, the aligner of the robot is configured to detect a notch within the wafer and control orientation of the wafer in relation to the notch prior to delivery to the process module.

26. The robot of claim 19, wherein the consumable part is made of a first part and a second part, and a first code is disposed on a surface of the first part and a second code is disposed on a surface of the second part, wherein the first code of the first part is separated by a predefined distance from the second code of the second part, and
wherein the set of instructions provided to said robot include a third instruction to move said consumable part to allow the first code disposed on the first part to be brought to the read orientation in relation to the fiducial marker to allow capture of an image of the first code, and a fourth instruction to move said consumable part to allow the second code disposed on the second part to be brought to the read orientation in relation to the fiducial marker to allow capture of an image of the second code disposed on the second part.

27. A machine vision system for tracking and verifying a consumable part in a substrate processing system, comprising:
a mounting enclosure with a consumable parts station for storing consumable parts within, the mounting enclosure has an opening towards an equipment front end module (EFEM) of the substrate processing system to enable a robot in the EFEM to retrieve a consumable part from the consumable parts station;
a controller configured to cause the robot in the EFEM to move the consumable part from the consumable parts station via the opening of the mounting enclosure and to position the code of the consumable part within a field of view of an image capture system;
the image capture system is configured to capture an image of a code on the consumable part, the image capture system includes at least a camera and a light source, the image capture system is positioned near the opening of the mounting enclosure, wherein said camera and the light source are oriented to point toward the opening of the mounting enclosure; and
a processor communicatively connected to the image capture system and the controller, the processor is configured to process and analyze the image of the code captured by the image capture system and verify that the consumable part is suitable for a subsequent operation.
